(19) United States
(12) Patent Application Publication
(10) Pub. No.: US 2025/0336851 A1
(43) Pub. Date: Oct. 30, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Harry-HakLay CHUANG, Zhubei City (TW); Wei-Cheng WU, Zhubei City (TW); Fang-Lan CHU, Taichung City (TW); Chih-Peng TSAI, Changhua County (TW)

(21) Appl. No.: 18/644,377

(22) Filed: Apr. 24, 2024

(51) Int. Cl. H01L 23/00; H01L 25/065

(52) U.S. Cl. CPC H01L 24/03; H01L 24/05; H01L 24/08; H01L 24/80; H01L 24/94; H01L 25/0657; H01L 2224/03452; H01L 2224/03831; H01L 2224/03845; H01L 2224/05624; H01L 2224/05644; H01L 2224/05647; H01L 2224/05657; H01L 2224/05666; H01L 2224/05676; H01L 2224/05684; H01L 2224/08145; H01L 2224/80357; H01L 2224/80379; H01L 2224/80895; H01L 2224/80896; H01L 2225/06565; H01L 2924/04642; H01L 2924/0504; H01L 2924/05442; H01L 2924/059

(57) ABSTRACT

A thick bonding layer is formed over the surface of a semiconductor wafer such that a top surface of the bonding layer in an edge region is at a greater vertical height than a bottom surface of the bonding layer in a non-edge region of the semiconductor wafer. A photoresist material is then deposited across the surface of the semiconductor wafer and patterned such that the photoresist material remains only on the edge region of the semiconductor wafer. The bonding layer in the non-edge region is etched based on the photoresist material such that the top surface of the bonding layer is substantially flat and uniform across the edge region and the non-edge region of the semiconductor wafer.

### BACKGROUND

Semiconductor dies may be bonded together at a bonding interface to form a vertically stacked three-dimensional integrated circuit (3DIC) semiconductor device. The semiconductor dies may be bonded together in a wafer-to-wafer bonding arrangement in which the semiconductor dies are manufactured on separate semiconductor wafers, and the semiconductor wafers are bonded together face-to-face. Alternatively, the semiconductor dies may be bonded together in a die-to-wafer bonding arrangement and/or another bonding arrangement in which the semiconductor dies are directly bonded together.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a semiconductor device described herein.

FIG. 2 is a diagram of an example of a semiconductor device described herein.

FIGS. 3A-3E are diagrams of an example implementation of forming a semiconductor die described herein.

FIGS. 4A-4U are diagrams of an example implementation of an edge rebuilding process described herein.

FIGS. 5A-5D are diagrams of an example implementation of forming a semiconductor device described herein.

FIGS. 6A-6F are diagrams of an example implementation of an edge rebuilding process described herein.

FIG. 7 is a diagram of an example of a semiconductor device described herein.

FIG. 8 is a diagram of an example of a semiconductor device described herein.

FIG. 9 is a flowchart of an example process associated with rebuilding an edge region of a semiconductor wafer described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

At a bonding interface between a first semiconductor wafer and a second semiconductor wafer, metal-to-metal bonds may be formed between metal structures in the semiconductor dies on the first semiconductor wafer and semiconductor dies on the second semiconductor wafer. Moreover, dielectric-to-dielectric bonds may be formed between bonding layers on each of the first semiconductor wafer and the second semiconductor wafer. In some cases, nonuniformities across the surfaces of one or more of the semiconductor wafers on which the semiconductor dies are formed may result in only partial bonding of the bonding layers across the semiconductor dies. The nonuniformities may occur at the edges around the perimeters of one or more of the semiconductor wafers. The nonuniformities may include sloping in the surfaces at the edges of one or more of the semiconductor wafers, which may be referred to as edge roll-off. The sloping in the surfaces at the edges may result in the semiconductor wafers not being bonded at the edges of the semiconductor wafers. In other words, a gap between the edges of the semiconductor wafers may occur, and this gap may result in a weak point in the bonding interface in that humidity ingress in the bonding interface may occur through the gap, and/or cracking and delamination of the semiconductor wafers may start at the gap.

In some implementations described herein, the slope in the surface of a semiconductor wafer at an edge region of the semiconductor wafer is filled in prior to bonding the semiconductor wafer with another semiconductor wafer to minimize or prevent the likelihood of a gap forming between the edges of the semiconductor wafers. To fill in the slope in the surface of the semiconductor wafer, a thick bonding layer is formed over the surface of the semiconductor wafer such that a top surface of the bonding layer in the edge region is at a greater vertical height than a bottom surface of the bonding layer in a non-edge region of the semiconductor wafer. A photoresist material is then deposited across the surface of the semiconductor wafer and patterned such that the photoresist material remains only on the edge region of the semiconductor wafer. The photoresist material is used to etch the bonding layer. Forming the bonding layer such that the top surface of the bonding layer in the edge region is at a greater vertical height than the bottom surface of the bonding layer in the non-edge region of the semiconductor wafer enables the bonding layer in the non-edge region to be etched based on the photoresist material such that the top surface of the bonding layer is substantially flat and uniform across the edge region and the non-edge region of the semiconductor wafer. In other words, the bonding layer is formed to a sufficient thickness in the edge region to enable the bonding layer to be thinned in the non-edge region such that little to no slope in the edge region remains after the bonding layer is etched. A photoresist material that has little to no etch selectivity relative to the bonding layer may be used such that the photoresist material is fully removed when the bonding layer is etched, which prevents contamination in a subsequent planarization operation to planarize the bonding layer.

Rebuilding the edge region of the semiconductor wafer using the photoresist material may be faster in that fewer processing operations (e.g., fewer deposition operations, fewer etch operations, fewer planarization operations) are performed than other edge rebuilding techniques, such as those that include rebuilding the edge region of the semiconductor wafer by depositing multiple layers of the same material as the bonding layer in the edge region on the semiconductor wafer. Additionally and/or alternatively, rebuilding the edge of the semiconductor wafer using the photoresist material may be less costly than other edge rebuilding techniques in that lower cost processing techniques, such as low-complexity wafer edge exposure (WEE) photolithography patterning and developing, may be utilized.

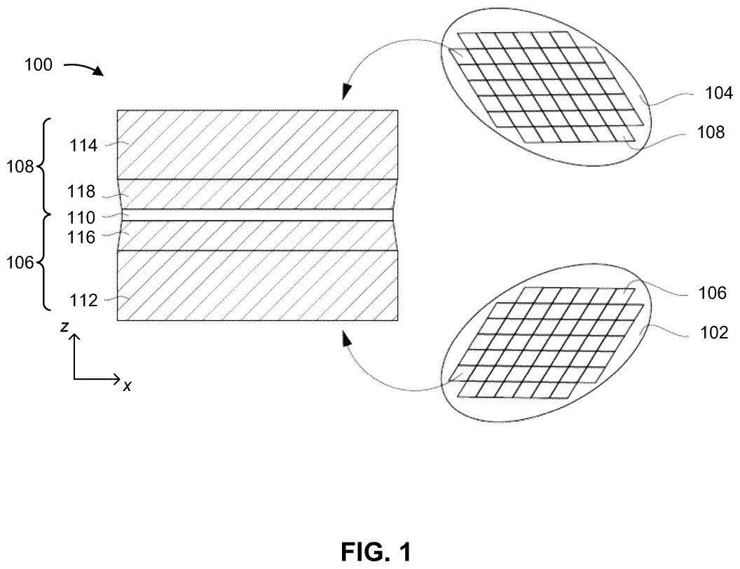

FIG. 1 is a diagram of an example of a semiconductor device 100 described herein. As shown in FIG. 1, the semiconductor device 100 is formed by bonding a semiconductor wafer 102 and a semiconductor wafer 104. For example, a bonding tool may be used to perform a bonding operation to bond the semiconductor wafer 102 and the semiconductor wafer 104 by forming metal-to-metal bonds and/or dielectric-to-dielectric bonds between the semiconductor wafer 102 and the semiconductor wafer 104. In the bonding operation, semiconductor dies 106 on the semiconductor wafer 102 are bonded with associated semiconductor dies 108 on the semiconductor wafer 104 to form semiconductor devices 100 (e.g., stacked semiconductor devices). The semiconductor devices 100 are then diced and packaged. Other processing steps may be performed to form the semiconductor devices 100.

A semiconductor die 106 and the semiconductor die 108 may be bonded at a bonding interface 110. The semiconductor device 100 includes a stacked semiconductor device in that the semiconductor die 106 and the semiconductor die 108 are stacked or vertically arranged in a z-direction in the semiconductor device 100. The semiconductor die 106 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 106 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 108 may include the same type of semiconductor die as the semiconductor die 106, or may include a different type of semiconductor die.

As further shown in FIG. 1, the semiconductor die 106 may include a device layer 112, and the semiconductor die 108 may include a device layer 114. The device layers 112 and 114 may include the integrated circuit devices of the semiconductor dies 106 and 108, respectively. The integrated circuit devices may include transistors, pixel sensors, capacitors, resistors, other active circuit devices and/or other passive circuit devices, among other examples.

The semiconductor die 106 may include an interconnect layer 116 above the device layer 112. The semiconductor die 108 may include an interconnect layer 118 below the device layer 114. The interconnect layers 116 and 118 may each include conductive structures that interconnect the integrated circuit devices of the device layers 112 and 114, respectively. Additionally and/or alternatively, the interconnect layers 116 and 118 may each include conductive structures that electrically connect the semiconductor dies 106 and 108.

The bonding interface 110 may be located between the interconnect layers 116 and 118 and may include portions of each of the interconnect layers 116 and 118. The bonding interface 110 may include conductive structures of the interconnect layers 116 and 118 that are bonded together by metal-to-metal bonds, and/or dielectric layers of the interconnect layers 116 and 118 that are bonded together by dielectric-to-dielectric bonds.

As indicated above, FIG. 1 is provided as an example. Other examples may differ from what is described with regard to FIG. 1.

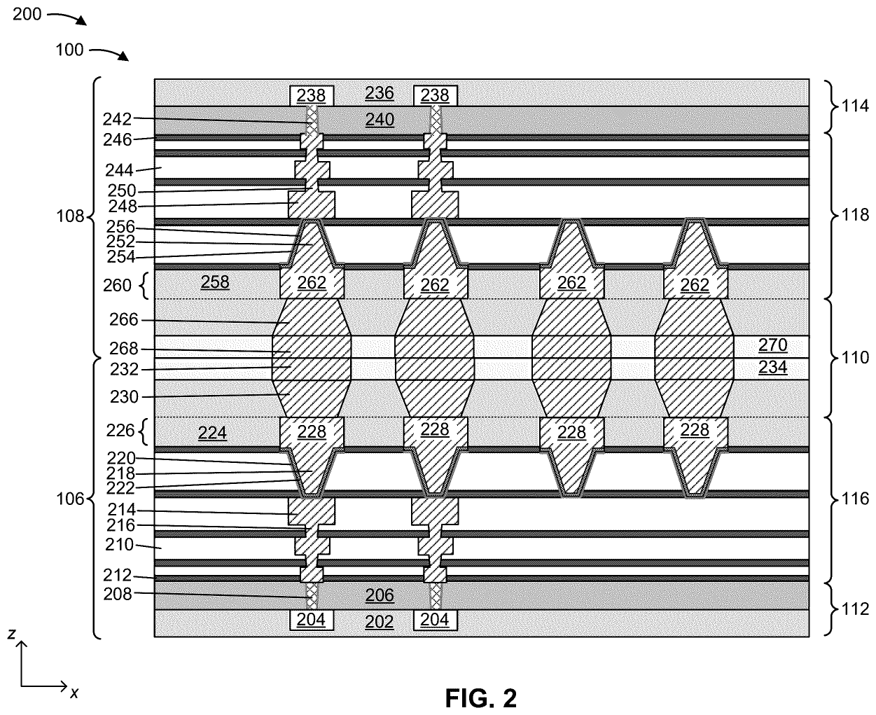

FIG. 2 is a diagram of an example 200 of a semiconductor device 100 described herein. FIG. 2 illustrates a cross-sectional view of the semiconductor device 100 in which the details of the semiconductor dies 106 and 108 are shown. In particular, FIG. 2 further illustrates details of the device layers 112 and 114, details of the interconnect layers 116 and 118, and details of the bonding interface 110.

As shown in FIG. 2, the device layer 112 of the semiconductor die 106 includes a substrate 202. The substrate 202 may correspond to a portion of the semiconductor wafer 102 on which the semiconductor die 106 is formed. The substrate 202 may include a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 202 may extend in an x-direction and/or in a y-direction in the semiconductor die 106.

The device layer 112 of the semiconductor die 106 includes integrated circuit devices 204 in the substrate 202 and/or on the substrate 202. The integrated circuit devices 204 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

A dielectric layer 206 of the device layer 112 is included over the substrate 202. The dielectric layer 206 includes an interlayer dielectric (ILD) layer, an etch stop layer (ESL), and/or another type of dielectric layer. In some implementations, portions of the integrated circuit devices 204 are included in the dielectric layer 206. For example, gate structures of the transistors of the integrated circuit devices 204 may be included in the dielectric layer 206, and source/drain regions and channel regions of the transistors may be included in the substrate 202. Additionally and/or alternatively, contacts 208 for the integrated circuit devices 204 may be included in the dielectric layer 206. The contacts 208 may include plugs, vias, pads, and/or other types of electrical contacts. In some implementations, an integrated circuit device 204 includes one or more source/drain contacts and one or more gate contacts. The contacts 208 may include one or more electrically conductive materials such as tungsten (W), cobalt (Co), ruthenium (Ru), and/or titanium (Ti), among other examples. In some implementations, one or more liner layers are included between the contacts 208 and the dielectric layer 206 to promote adhesion between the contacts 208 and the dielectric layer 206. The liner layers may include tantalum nitride (TaN), titanium nitride (TiN), and/or another suitable liner layer.

The dielectric layer 206 includes dielectric material(s) that enable various portions of the substrate 202 and/or the integrated circuit devices 204 to be selectively etched or protected from etching, and/or to electrically isolate the integrated circuit devices 204 in the device layer 112. The dielectric layer 206 includes a silicon nitride (SiₓN_{y}), an oxide (e.g., a silicon oxide (SiOₓ) and/or another oxide material), and/or another type of dielectric material. The dielectric layer 206 may extend in the x-direction and/or in the y-direction in the semiconductor die 106.

An interconnect layer 116 of the semiconductor die 106 is included above the substrate 202 and above the integrated circuit devices 204. In some implementations, one or more integrated circuit devices 204 are included in the interconnect layer 116 (e.g., a backend memory device, a backend resistor, a backend capacitor, a radio frequency (RF) switch, an optical modulator, a waveguide). The interconnect layer 116 includes a plurality of dielectric layers that are arranged in a direction (e.g., the z-direction) that is approximately perpendicular to the substrate 202. The dielectric layers may include backend dielectric layers 210 (e.g., ILD layers, intermetal dielectric (IMD) layers) and ESLs 212 that are arranged in an alternating manner in the z-direction. The backend dielectric layers 210 may each include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material. In some implementations, a backend dielectric layer 210 includes an extreme low dielectric constant (ELK) dielectric material having a dielectric constant that is less than approximately 2.5. The ESLs 212 may each include a silicon nitride (SiₓN_{y}), silicon carbide (SiC), silicon oxynitride (SiON), and/or another suitable dielectric material. In some implementations, a backend dielectric layer 210 and an ESL 212 include different dielectric materials to provide etch selectivity to enable various structures to be formed in the interconnect layer 116. The backend dielectric layers 210 and the ESLs 212 may each extend in the x-direction and/or in the y-direction in the semiconductor die 106.

The interconnect layer 116 includes a plurality of conductive interconnects in the backend dielectric layers 210 and in the ESLs 212. The conductive interconnects are electrically coupled and/or physically coupled with one or more of the integrated circuit devices 204 in the device layer 112 and/or in the interconnect layer 116. The conductive interconnects correspond to circuit routing that enables signals and/or power to be provided to and/or from the integrated circuit devices 204. The conductive interconnects may include a combination of conductive structures 214 (e.g., trenches, conductive lines) that are interconnected by interconnect structures 216 (e.g., vias). The conductive structures 214 and interconnect structures 216 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As shown in FIG. 2, the conductive interconnects of the interconnect layer 116 may be arranged in in a vertical manner (e.g., in the z-direction) to facilitate electrical signals and/or power to be routed between the device layer 112, between integrated circuit devices 204 through the interconnect layer 116, and/or between the integrated circuit devices 204 and the semiconductor die 108. The conductive interconnects may be arranged in alternating layers of metallization layers (referred to as “M”-layers) and via layers (referred to as “V”-layers). Each metallization layer may include one or more conductive structures 214 laterally arranged in an x-y plane in the interconnect layer 116, and each via layer may include one or more interconnect structures 216 laterally arranged in an x-y plane in the interconnect layer 116. As an example, a metal-0 (M0) layer (including one or more conductive structures 214) may be located at the bottom of the interconnect layer 116 and may be coupled with the contacts 208 of the integrated circuit devices 204 in the device layer 112, a via-1 (V1) layer (including one or more interconnect structures 216) may be located above and coupled with the M1 layer in the interconnect layer 116, a metal-1 layer (M1) layer may be located above and coupled with the V1 layer in the interconnect structure 216, a via-2 (V2) layer may be located above and coupled with the M1 layer in the interconnect layer 116, a metal-2 layer (M2) layer may be located above and electrically coupled with the V2 layer in the interconnect layer 116, and so on. In some implementations, the interconnect layer 116 includes nine (9) stacked metallization layers (e.g., M0-M8). In some implementations, the interconnect layer 116 includes another quantity of stacked metallization layers.

The interconnect layer 116 includes a top via layer and a top metallization layer. The top via layer is the top-most via layer in the interconnect layer 116 and is the via layer that is closest to the bonding interface 110. Similarly, the top metallization layer is the top-most metallization layer in the interconnect layer 116 and is the metallization layer that is closest to the bonding interface 110. The top via layer includes interconnect structures 218 in a backend dielectric layer 210 and/or in an ESL 212. The interconnect structures 218 may include copper (Cu) structures and/or another type of metal structures. Barrier layers 220 may be included between the interconnect structures 218 and the backend dielectric layer 210 and/or the ESL 212, and may be included to prevent or minimize diffusion of material (e.g., copper atoms) of the interconnect structures 218 into the surrounding backend dielectric layers 210 and/or the surrounding ESLs 212. Examples of barrier layers 220 include tantalum nitride (TaN) and/or titanium nitride (TiN), among other examples. In some implementations, adhesion layers 222 are included between the interconnect structures 218 and the barrier layers 220. The adhesion layers 222 may include material(s) that promote adhesion between the interconnect structures 218 and the surrounding backend dielectric layers 210 and/or the surrounding ESLs 212. In some implementations, the adhesion layers 222 include copper seed layers. In some implementations, the adhesion layers 222 include another type of adhesion material that promotes adhesion of copper to dielectric materials.

A backend dielectric layer 224 may be included over the backend dielectric layers 210 and the ESLs 212 of the interconnect layer 116. The backend dielectric layer 224 may be partially included in the bonding interface 110 between the semiconductor die 106 and the semiconductor die 108. The backend dielectric layer 224 may include one or more ELK dielectric materials such as carbon doped silicon oxide (C—SiOₓ), amorphous fluorinated carbon (a-CₓF_{y}), parylene, bis-benzocyclobutenes (BCB), polytetrafluoroethylene (PTFE), and/or a silicon oxycarbide (SiOC) polymer. In some implementations, the ELK dielectric material(s) for the backend dielectric layer 224 include porous hydrogen silsesquioxane (HSQ), porous methyl silsesquioxane (MSQ), porous polyarylether (PAE), and/or porous silicon oxide (SiOₓ), among other examples. Additionally and/or alternatively, the backend dielectric layer 224 may include silicon oxide (SiOₓ such as SiO₂), USG, BSG, and/or another suitable dielectric material.

A top metallization layer 226 is included in the backend dielectric layer 224. The top metallization layer 226 is above and electrically coupled with the top via layer in the interconnect layer 116. The top metallization layer 226 includes a plurality of types of conductive structures 228. One or more of the conductive structures 228 in the top metallization layer 226 may be is coupled with a bonding via 230 in the backend dielectric layer 224. The bonding vias 230 each include a via structure that is elongated in the z-direction. The bonding vias 230 may each be physically coupled and electrically coupled with an associated bonding pad 232. The bonding pads 232 are included on the bonding vias 230 such that the bonding pads 232 and the bonding vias 230 are physically coupled and electrically coupled. The bonding vias 230 and the bonding pads 232 may each include tungsten (W), cobalt (Co), ruthenium (Ru), titanium (Ti), aluminum (Al), copper (Cu), gold (Au), and/or a combination thereof, among other examples of electrically conductive metals.

The bonding pads 232 are included in a bonding layer 234 that is above and/or on the backend dielectric layer 224. The bonding layer 234 may be included in the bonding interface 110 and may include one or more electrically insulating materials. For example, the bonding layer 234 may include an oxide-containing dielectric material or a nitride-containing material such as a high density plasma (HDP) oxide material, a silicon oxide (SiOₓ), a silicon nitride (SiₓN_{y}), silicon carbide (SiC), silicon oxynitride (SiON), and/or another suitable dielectric material. Alternatively, the bonding layer 234 may include an oxide-containing material (e.g., SiOₓ such as SiO₂) that is formed using one or more precursors that include an orthosilicate material. Examples of such orthosilicate materials include esters of orthosilicate acid such as tetraethyl orthosilicate (TEOS), among other examples.

As further shown in FIG. 2, the semiconductor die 108 may include a similar combination and/or arrangement of structures and/or layers as the semiconductor die 106. For example, the semiconductor die 108 may include a combination of a substrate 236, integrated circuit devices 238, a dielectric layer 240, and contacts 242 in the device layer 114 of the semiconductor die 108, similar to the device layer 112 of the semiconductor die 106. As another example, the semiconductor die 108 may include a combination of backend dielectric layers 244, ESLs 246, conductive structures 248, and interconnect structures 250 in the interconnect layer 118 of the semiconductor die 108, similar to the interconnect layer 116 of the semiconductor die 106. These layers and/or structures may have a reversed z-direction arrangement relative to the semiconductor die 106, which enables the semiconductor die 106 and the semiconductor die 108 to be bonded at the bonding interface 110 such that the interconnect layer 116 and the interconnect layer 118 are facing each other.

Moreover, the interconnect layer 118 includes a top via layer and a top metallization layer. The top via layer is the top-most via layer in the interconnect layer 118 and is the via layer that is closest to the bonding interface 110. Similarly, the top metallization layer is the top-most metallization layer in the interconnect layer 118 and is the metallization layer that is closest to the bonding interface 110. The top via layer includes interconnect structures 252 in a backend dielectric layer 244 and/or in an ESL 246. The interconnect structures 252 may include copper (Cu) structures and/or another type of metal structures. Barrier layers 254 and/or adhesion layers 256 may be included between the interconnect structures 252 and the backend dielectric layer 244 and/or the ESL 246.

A backend dielectric layer 258 may be included over (or under) the backend dielectric layers 244 and the ESLs 246 of the interconnect layer 118. The backend dielectric layer 258 may be partially included in the bonding interface 110 between the semiconductor die 106 and the semiconductor die 108. The backend dielectric layer 258 may include similar material(s) as the backend dielectric layer 224, and/or may include different material(s).

A top metallization layer 260 is included in the backend dielectric layer 258. The top metallization layer 260 is below and may be electrically coupled with one or more of the interconnect structures 252 in the interconnect layer 118. The top metallization layer 260 includes a plurality of types of conductive structures 262. One or more of the conductive structures 262 in the top metallization layer 260 may be is coupled with a bonding via 266 in the backend dielectric layer 258. The bonding vias 266 each include a via structure that is elongated in the z-direction. The bonding vias 266 may each be physically coupled and electrically coupled with an associated bonding pad 268. The bonding pads 268 are included on the bonding vias 266 such that the bonding pads 268 and the bonding vias 266 are physically coupled and electrically coupled. The bonding vias 266 and the bonding pads 268 may each include tungsten (W), cobalt (Co), ruthenium (Ru), titanium (Ti), aluminum (Al), copper (Cu), gold (Au), and/or a combination thereof, among other examples of electrically conductive metals.

The bonding pads 268 are included in a bonding layer 270 that is below the backend dielectric layer 258. The bonding layer 270 may be included in the bonding interface 110 and may include one or more electrically insulating materials. For example, the bonding layer 270 may include an oxide-containing dielectric material or a nitride-containing material such as a silicon oxide (SiOₓ), a silicon nitride (SiₓN_{y}), silicon carbide (SiC), silicon oxynitride (SiON), and/or another suitable dielectric material.

At the bonding interface 110, the bonding pads 232 of the semiconductor die 106 and the bonding pads 268 of the semiconductor die 108 are directly bonded by metal-to-metal bonds. Moreover, the bonding layer 234 of the semiconductor die 106 and the bonding layer 270 of the semiconductor die 108 are directly bonded by dielectric-to-dielectric bonds or insulator-to-insulator bonds.

As indicated above, FIG. 2 is provided as an example. Other examples may differ from what is described with regard to FIG. 2.

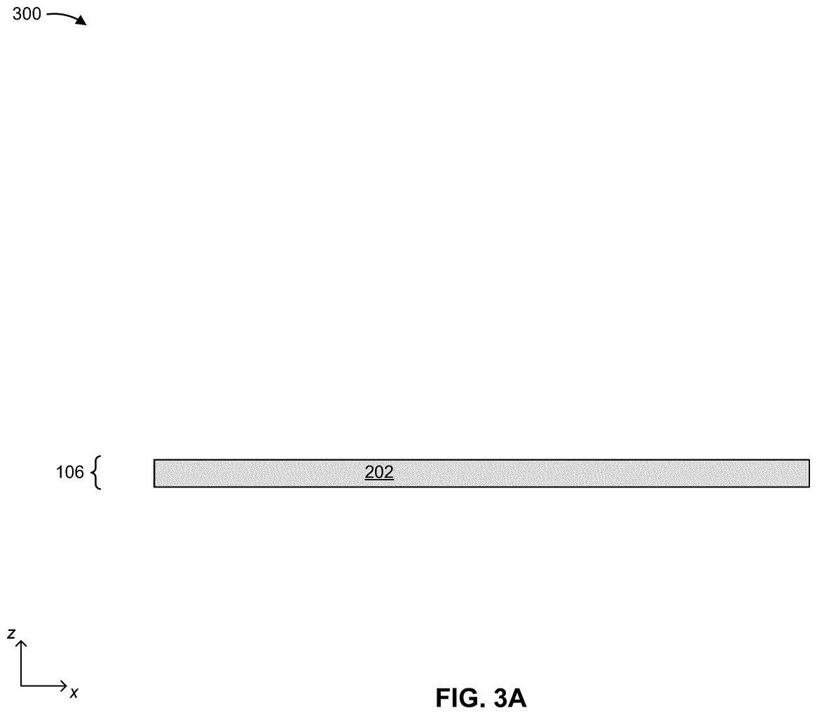

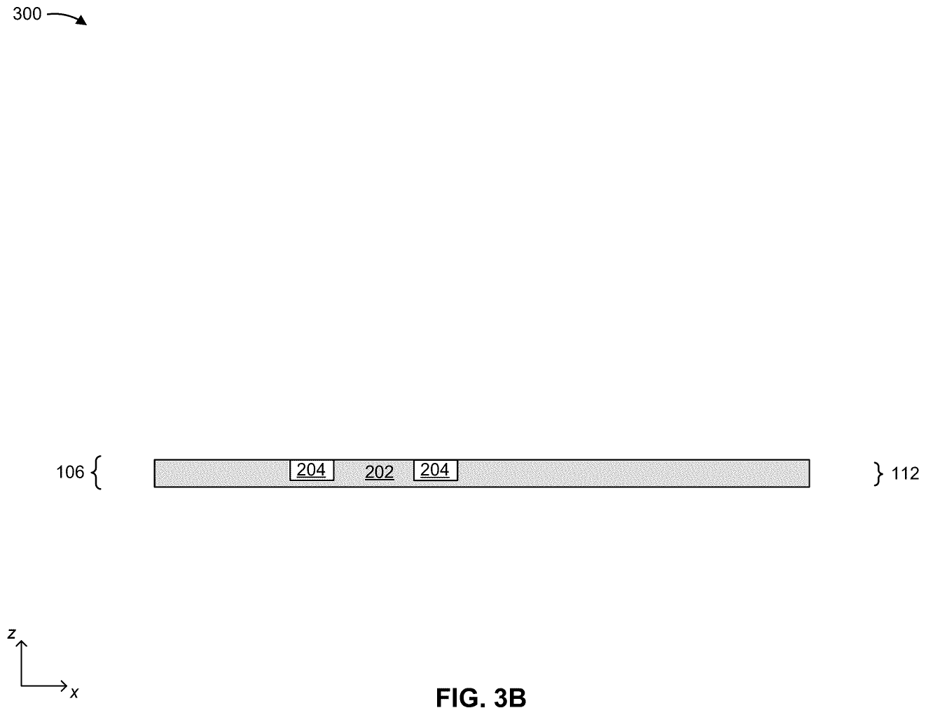

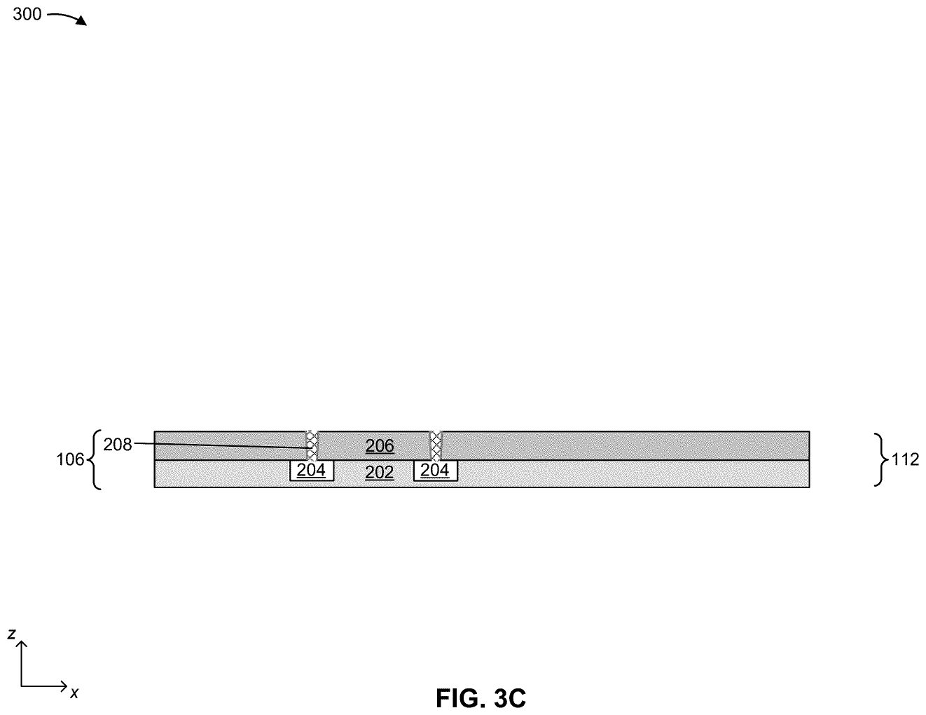

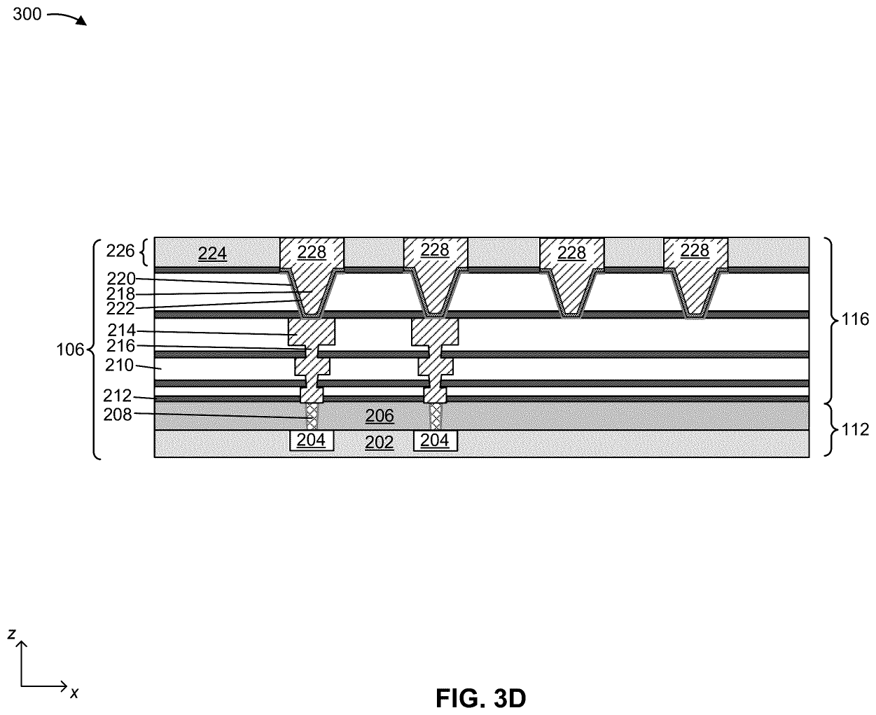

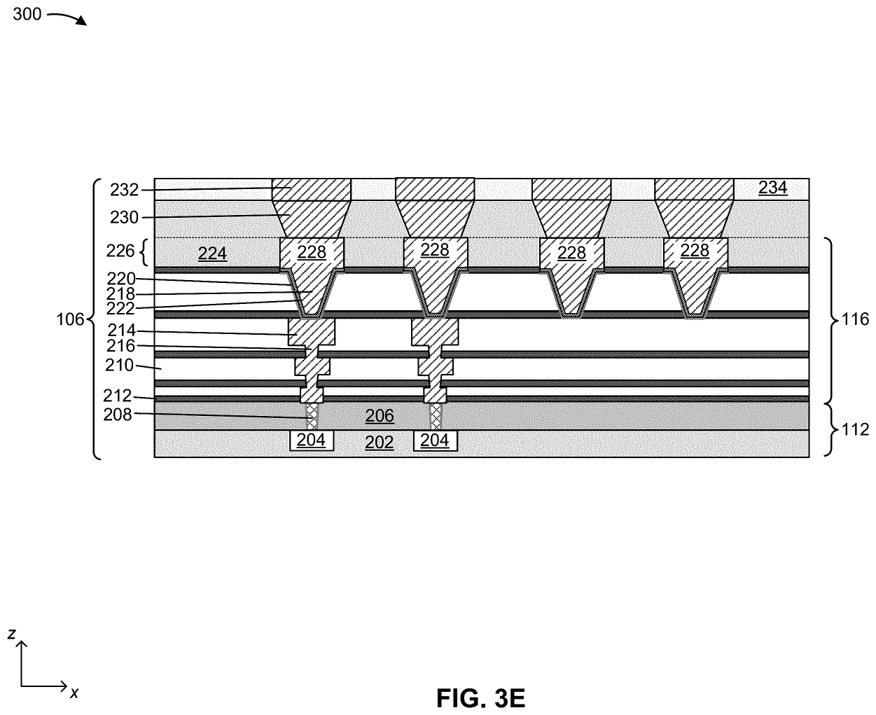

FIGS. 3A-3E are diagrams of an example implementation 300 of forming a semiconductor die 106 described herein. In some implementations, one or more of the semiconductor processing tools may be used to perform one or more of the semiconductor processing operations described in connection with FIGS. 3A-3E, such as a deposition tool, an exposure tool, a developer tool, an etch tool, an ion implantation tool, and/or a wafer/die transport tool, among other examples. In some implementations, one or more of the operations and/or techniques described in the example implementation 300 of forming a semiconductor die 106 may also be performed or used to form a semiconductor die 108.

Turning to FIG. 3A, the substrate 202 may be provided. The substrate 202 may be provided in the form of a semiconductor wafer (e.g., the semiconductor wafer 102) such as a silicon (Si) wafer. The semiconductor die 106 may be formed on the substrate 202 along with a plurality of other semiconductor dies 106.

As shown in FIG. 3B, the integrated circuit devices 204 may be formed in and/or on the substrate 202 in the device layer 112 of the semiconductor die 106. One or more semiconductor processing tools may be used to form one or more portions of the integrated circuit devices 204. For example, a deposition tool may be used to perform various deposition operations to deposit layers of the integrated circuit devices 204, and/or to deposit photoresist layers for etching the substrate 202 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 202 and/or portions of the deposited layers to form the integrated circuit devices 204. As another example, a planarization tool may be used to planarize portions of the integrated circuit devices 204. As another example, an ion implantation tool may be used to implant ions in the substrate 202 to dope portions of the substrate 202 with one or more types of dopants (e.g., p-type dopants, n-type dopants).

As shown in FIG. 3C, a deposition tool is used to deposit the dielectric layer 206 over and/or on the substrate 202 and over and/or on the integrated circuit devices 204. A deposition tool, an exposure tool, and a developer tool may be used to form a patterned masking layer (e.g., a patterned photoresist layer, a patterned hard mask layer) on the dielectric layer 206. An etch tool may be used to form recesses in the dielectric layer 206, and a deposition tool may be used to form contacts 208 in the recesses such that the contacts 208 are physically coupled and/or electrically coupled with the integrated circuit devices 204.

As shown in FIG. 3D, a first portion of the interconnect layer 116 is formed above the device layer 112. Forming the first portion of the interconnect layer 116 may include forming a plurality of alternating layers of backend dielectric layers 210 and ESLs 212, and forming alternating layers of conductive structures 214 and interconnect structures 216.

The first portion of the interconnect layer 116 may be manufactured in series of sequential layers. For example, a deposition tool may be used to deposit an ESL 212 and a backend dielectric layer 210 each using a physical vapor deposition (PVD) technique, an atomic layer deposition (ALD) technique, a chemical vapor deposition (CVD) technique, an oxidation technique, and/or another deposition technique. In some implementations, a planarization tool is used to planarize the ESL 212 and/or the backend dielectric layer 210. Recesses may be formed in and/or through the ESL 212 and the backend dielectric layer 210, and a deposition tool may be used to deposit an interconnect structure 216 and a conductive structure 214 in each of the recesses. The preceding set of operations may be repeated for each subsequent layer of the first portion of the interconnect layer 116. In some implementations, dual damascene processes are used for forming the layers of the first portion of the interconnect layer 116.

As further shown in FIG. 3D, another ESL 212 is formed, and the backend dielectric layer 224 is formed on the ESL 212. A deposition tool, using a PVD technique, an ALD technique, a CVD technique, an oxidation technique, and/or another type of deposition technique, may be used to deposit each of the ESL 212 and the backend dielectric layer 224. In some implementations, a planarization tool is used to planarize the top surface of the backend dielectric layer 224.

The interconnect structures 218 and associated barrier layers 220 and adhesion layers 222 are formed above one or more of the conductive structures 214, and the conductive structures 228 of the top metallization layer 226 may be formed in and/or through the backend dielectric layer 224. In some implementations, dual damascene recesses formed through a backend dielectric layer 224 and the underlying ESL 212, and into the topmost backend dielectric layer 210. The top surfaces of one or more of the topmost conductive structures 214 in the interconnect layer 116 are exposed through one or more of the recesses. A deposition tool may be used to form a photoresist layer on the backend dielectric layer 224. An exposure tool may be used to expose the photoresist layer to a radiation source to pattern the photoresist layer. A developer tool may be used to develop and remove portions of the photoresist layer to expose the pattern. An etch tool may be used to etch through the backend dielectric layer 224 and the underlying ESL 212, and into the topmost backend dielectric layer 210 to form the recesses. In some implementations, a photoresist removal tool removes the remaining portions of the photoresist layer (e.g., using a chemical stripper and/or another technique).

A deposition tool may be used to conformally deposit the barrier layers 220 and/or adhesion layers 222. A conformal deposition technique such as ALD may be used to conformally deposit the barrier layers 220 and/or adhesion layers 222. Alternatively, a CVD technique and/or another suitable deposition technique may be used to deposit the barrier layers 220 and/or adhesion layers 222. A deposition tool may be used to deposit the interconnect structures 218 and the conductive structures 228 the recesses. A CVD technique, a PVD technique, an ALD technique, an electroplating technique, and/or another suitable deposition technique may be used to deposit the interconnect structures 218 and the conductive structures 228. In some implementations, a planarization tool is used to perform a chemical mechanical planarization (CMP) operation or another type planarization operation to planarize the conductive structures 228 after the conductive structures 228 are deposited.

As shown in FIG. 3E, additional material of the backend dielectric layer 224 may be deposited. A deposition tool may be used to deposit the additional material of the backend dielectric layer 224 using a CVD technique, a PVD technique, an ALD technique, an oxidation technique, and/or another suitable deposition technique. In some implementations, a planarization tool is used to planarize the backend dielectric layer 224 after the additional material of the backend dielectric layer 224 is deposited.

The bonding vias 230 may be formed in the backend dielectric layer 224. In some implementations, one or more of the bonding vias 230 are formed on a conductive structure 228. To form the bonding vias 230, recesses may be formed in the backend dielectric layer 224 (e.g., over one or more of the conductive structures 228). The recesses may extend through the backend dielectric layer 224 to the conductive structures 228 such that the top surfaces of the conductive structures 228 are exposed through the recesses in the backend dielectric layer 224. In some implementations, over-etching may occur to ensure that the backend dielectric layer 224 is fully etched through to top surfaces of the conductive structures 228. In these implementations, some etching may occur into the top surfaces of the conductive structures 228.

In some implementations, a pattern in a photoresist layer is used to etch the backend dielectric layer 224 to form the recesses. In these implementations, a deposition tool may be used to form the photoresist layer on the backend dielectric layer 224. An exposure tool may be used to expose the photoresist layer to a radiation source to pattern the photoresist layer. A developer tool may be used to develop and remove portions of the photoresist layer to expose the pattern. An etch tool may be used to etch the backend dielectric layer 224 based on the pattern to remove the portions of the backend dielectric layer 224. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the backend dielectric layer 224 based on a pattern.

The bonding vias 230 are then deposited in the recesses. A deposition tool may be used to deposit the bonding vias 230 using a CVD technique, a PVD technique, an ALD technique, an electroplating technique, and/or another suitable deposition technique. In some implementations, a planarization tool is used to planarize the bonding vias 230 after the bonding vias 230 are deposited such that the top surfaces of the bonding vias 230 are approximately co-planar with the top surface of the backend dielectric layer 224.

As further shown in FIG. 3E, the bonding layer 234 is formed on the backend dielectric layer 224. The bonding layer 234 may also be formed on the bonding vias 230. A deposition tool may be used to deposit the bonding layer 234 using a CVD technique, a PVD technique, an ALD technique, an oxidation technique, and/or another suitable deposition technique. In some implementations, a planarization tool is used to planarize the bonding layer 234 after the bonding layer 234 is deposited.

The bonding pads 232 may be formed on the bonding vias 230 such that the bonding pads 232 extend through the bonding layer 234. To form the bonding pads 232, recesses are formed in the bonding layer 234 over the bonding vias 230. The recesses may extend through the bonding layer 234 to the bonding vias 230 such that the top surfaces of the bonding vias 230 are exposed through the recesses in the bonding layer 234.

In some implementations, a pattern in a photoresist layer is used to etch the bonding layer 234 to form the recesses. In these implementations, a deposition tool may be used to form the photoresist layer on the bonding layer 234. An exposure tool may be used to expose the photoresist layer to a radiation source to pattern the photoresist layer. A developer tool may be used to develop and remove portions of the photoresist layer to expose the pattern. An etch tool may be used to etch the bonding layer 234 based on the pattern to remove the portions of the bonding layer 234 above the bonding vias 230 to form the recesses. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the bonding layer 234 based on a pattern.

The bonding pads 232 are then deposited on the bonding vias 230 in the recesses. A deposition tool may be used to deposit the bonding pads 232 using a CVD technique, a PVD technique, an ALD technique, an electroplating technique, and/or another suitable deposition technique. In some implementations, a planarization tool is used to planarize the bonding pads 232 after the bonding pads 232 are deposited such that the top surfaces of the bonding pads 232 are approximately co-planar with the top surface of the bonding layer 234.

As indicated above, FIGS. 3A-3E are provided as an example. Other examples may differ from what is described with regard to FIGS. 3A-3E.

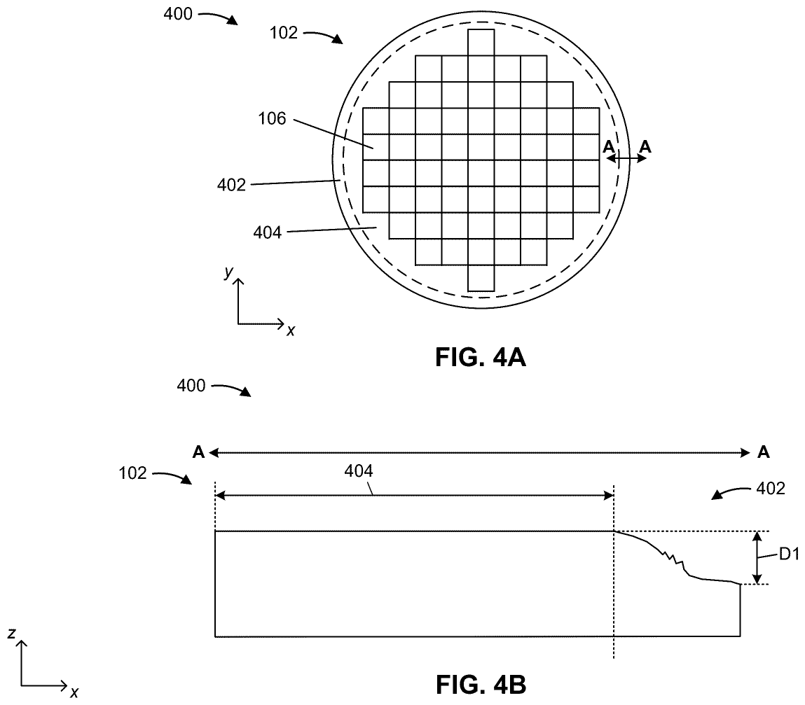

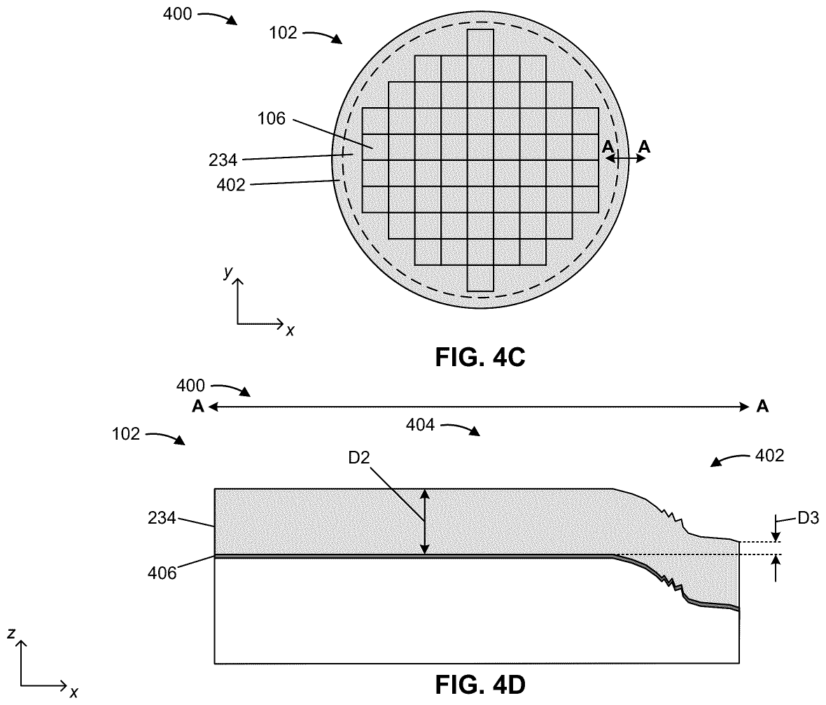

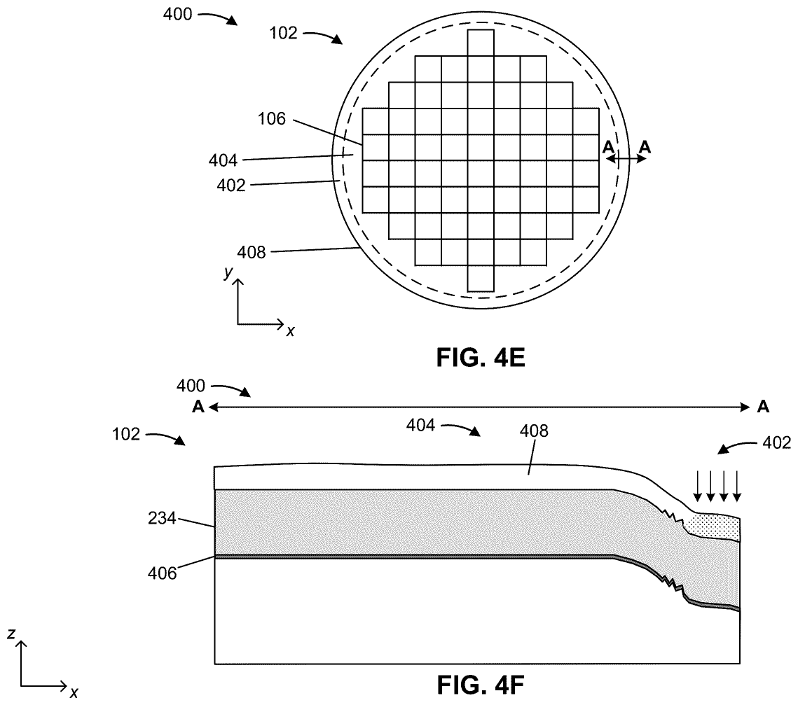

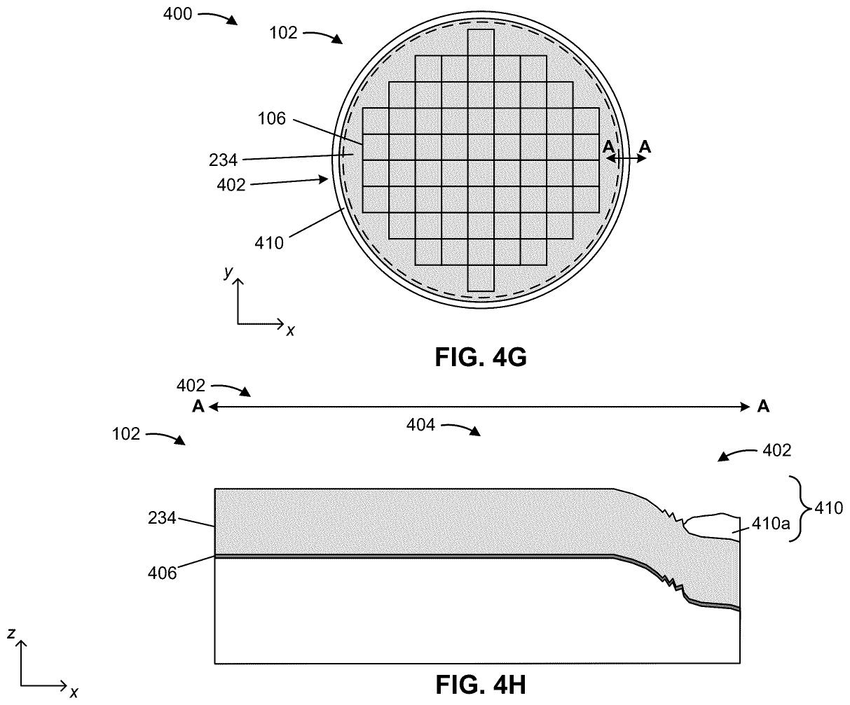

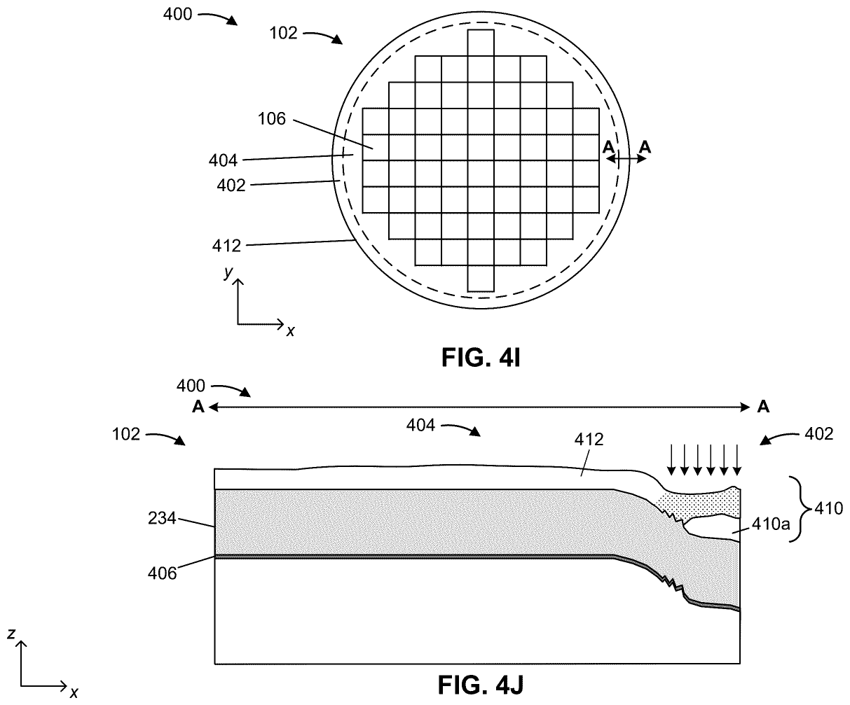

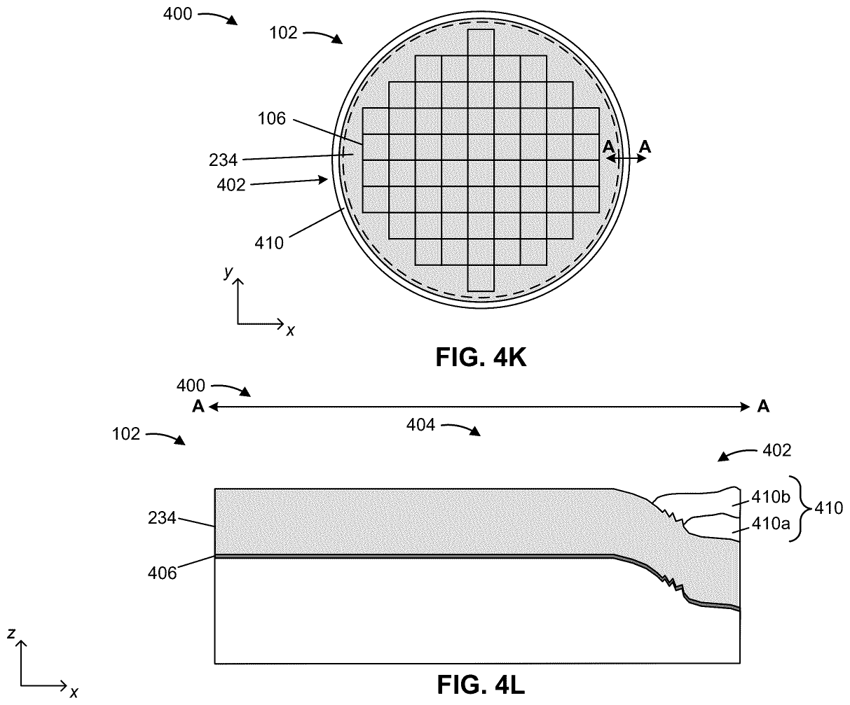

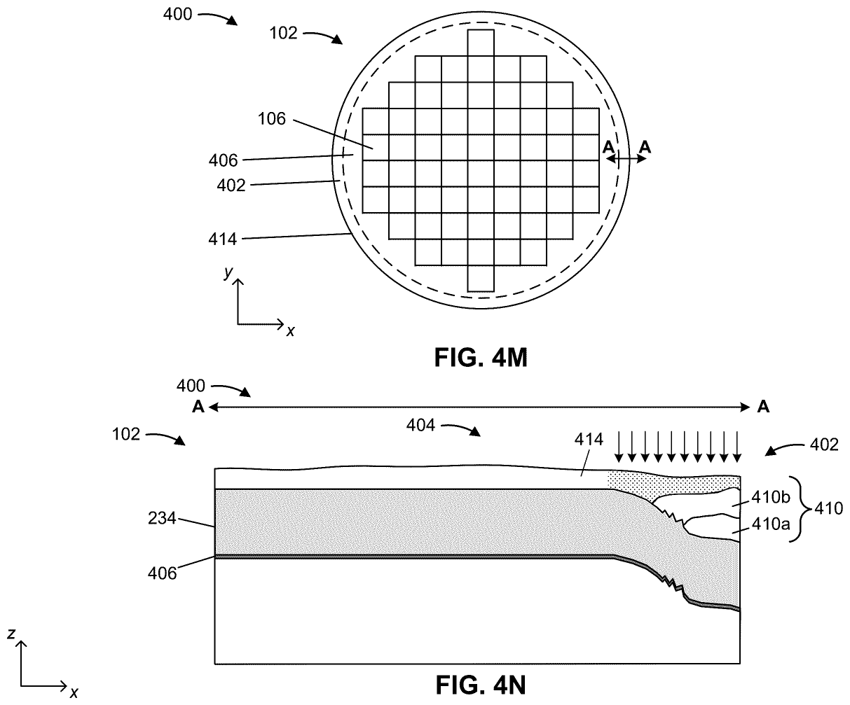

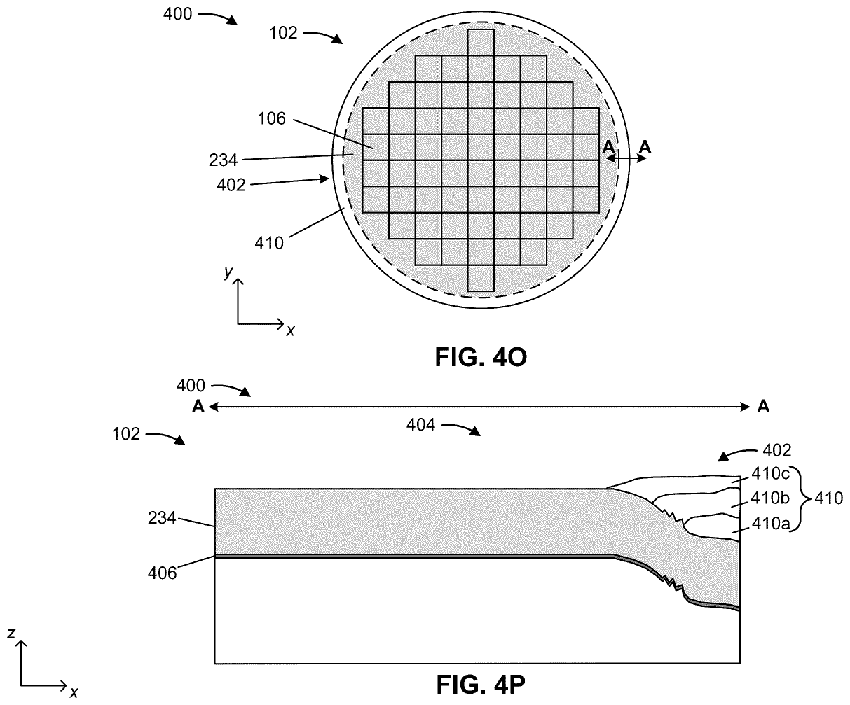

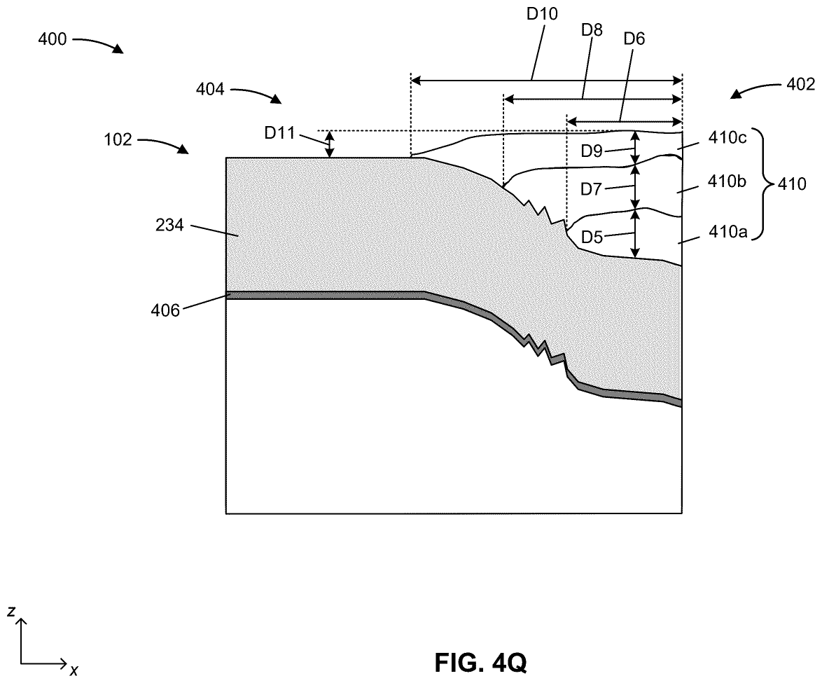

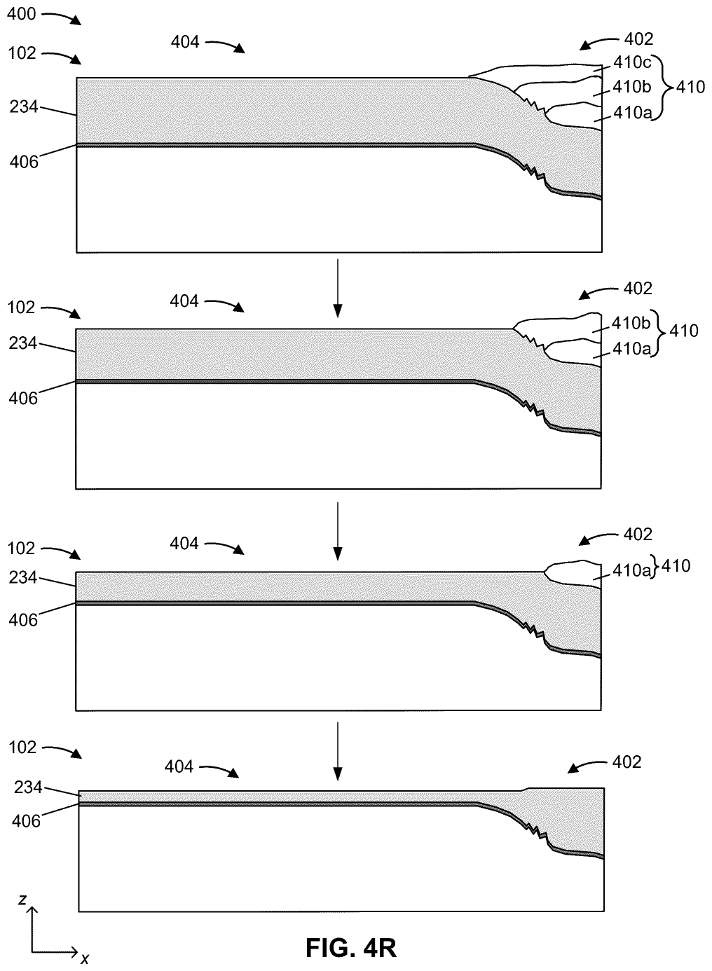

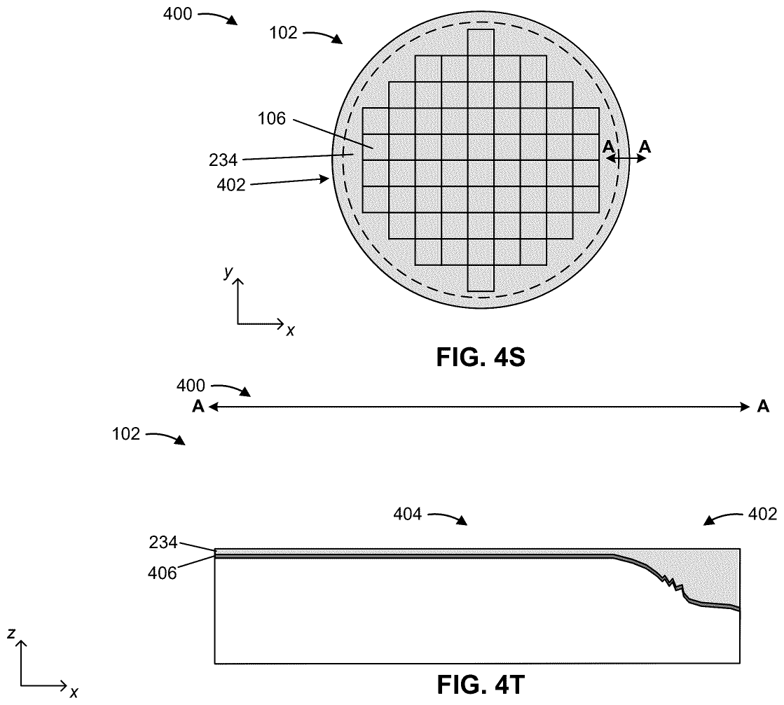

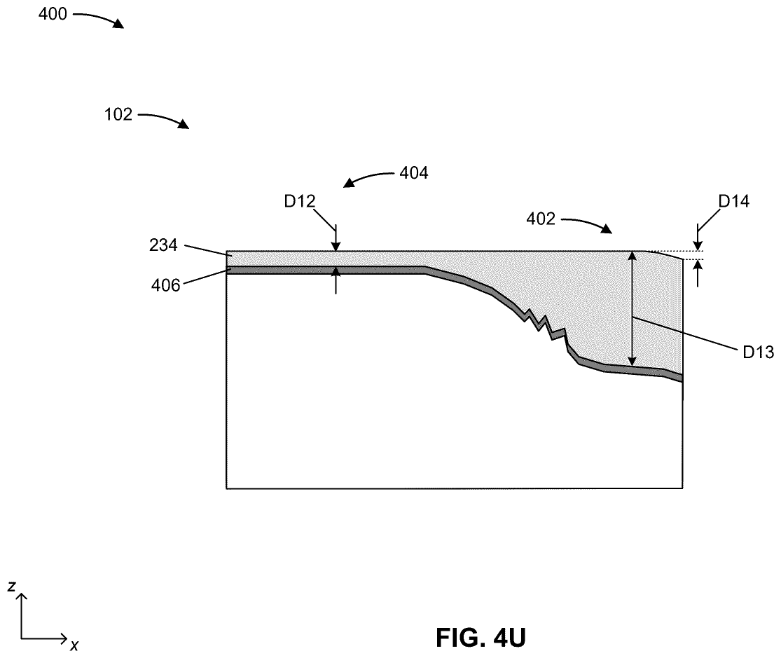

FIGS. 4A-4U are diagrams of an example implementation 400 of an edge rebuilding process described herein. The edge rebuilding process may be performed to build up an edge region of a semiconductor wafer. While the example implementation 400 is illustrated and described in connection with the semiconductor wafer 102, the process techniques of the example implementation 400 may be performed for rebuilding the edge of the semiconductor wafer 104. Alternatively, the process techniques of the example implementation 400 may be performed for rebuilding the edge of an individual semiconductor die 106 and/or for an individual semiconductor die 108 for die-to-wafer bonding or for die-to-die bonding.

Turning to FIGS. 4A and 4B, semiconductor dies 106 may be formed on the semiconductor wafer 102. In some implementations, one or more of the semiconductor dies 106 may be formed using techniques and/or by performing operations described in connection with FIGS. 3A-3D. In some implementations, one or more of the semiconductor dies 106 may be formed using other techniques and/or by performing other operations. The operations described in connection with FIGS. 4A-4U may be performed as a part of the operations described in connection with FIG. 3E to form the bonding layer 234 of the semiconductor dies 106 on the semiconductor wafer 102.

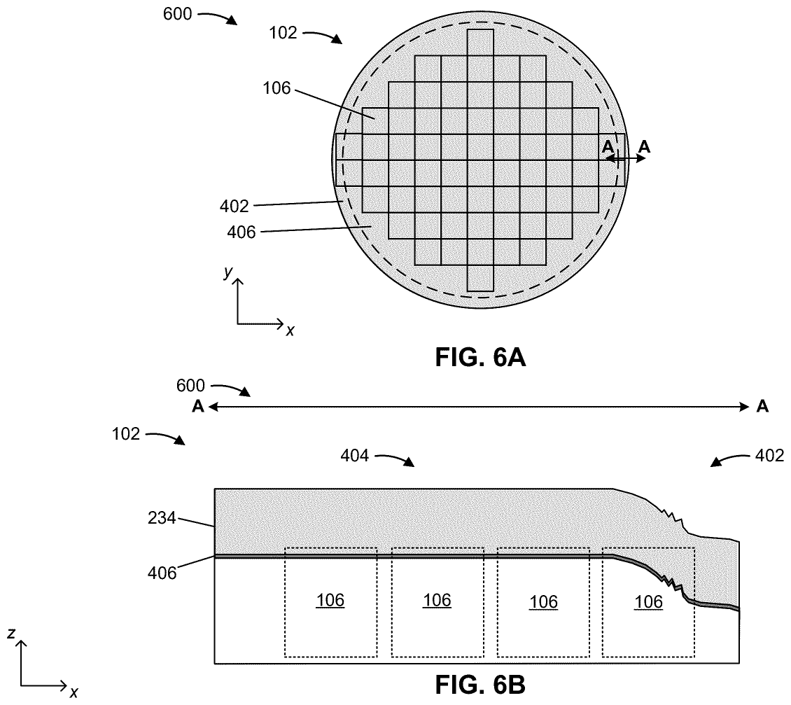

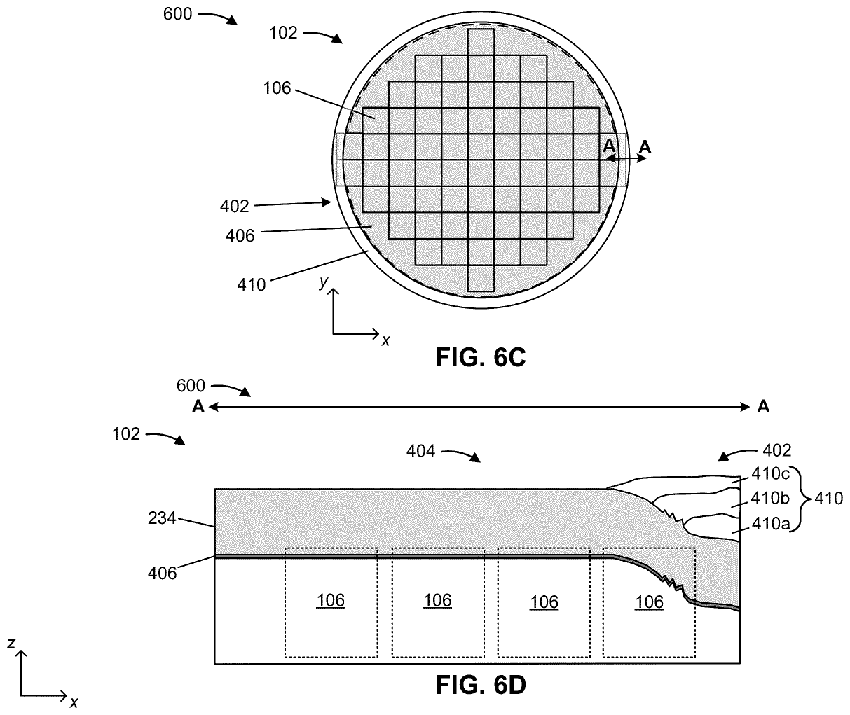

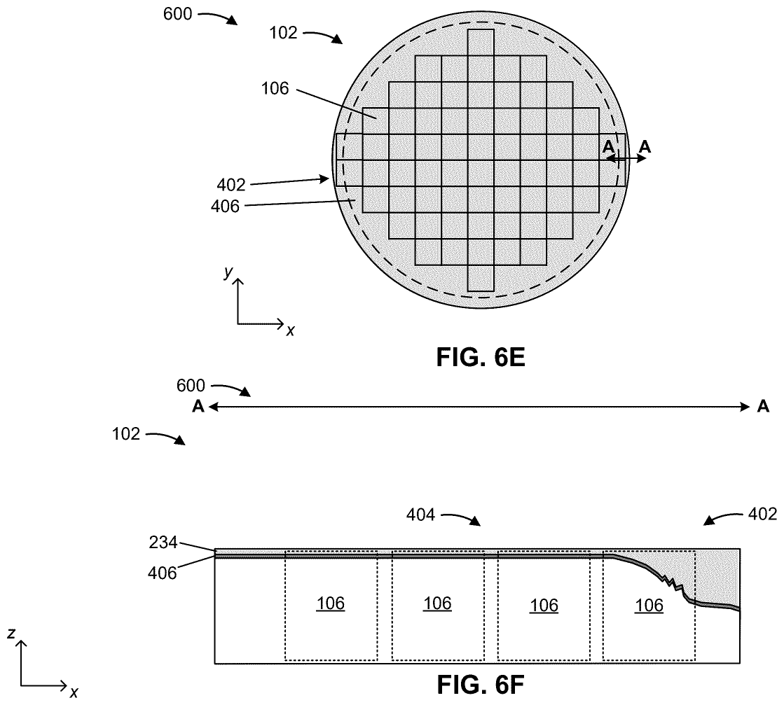

FIG. 4A illustrates a top view of the semiconductor wafer 102 and the associated semiconductor dies 106. FIG. 4B illustrates a cross-section view of the semiconductor wafer 102 along the line A-A in FIG. 4A. The cross-section view includes an edge region 402 around the outer perimeter of the semiconductor wafer 102 and a non-edge region 404. The non-edge region 404 is a portion of the semiconductor wafer 102 between the edge region 402 and a center of the semiconductor wafer 102. The semiconductor dies 106 may be formed in the non-edge region 404 of the semiconductor wafer 102 in the example implementation 400. An example implementation 600, illustrated and described in connection with FIGS. 6A-6F, includes an example in which at least a portion of one or more semiconductor dies 106 (referred to as edge dies) are formed in the edge region 402 of the semiconductor wafer 102.

As shown in FIG. 4B, the edge region 402 of the semiconductor wafer 102 may have a sloped top surface such that a height difference (indicated in FIG. 4B as dimension D1) occurs between the top surface of the semiconductor wafer 102 in the edge region 402 and the top surface of the semiconductor wafer 102 in the non-edge region 404. This is referred to as edge roll-off. Edge roll-off can occur in the edge region 402 of the semiconductor wafer 102 due to beveling of the edge of the semiconductor wafer 102, due to variation that occurs in planarization operations that are performed on the semiconductor wafer 102, due to uniformity control of semiconductor processes that are performed on the semiconductor wafer 102, and/or due to another cause.

As shown in FIGS. 4C and 4D, a thick layer of electrically insulating material is deposited over the top surface of the semiconductor wafer 102 to form the bonding layer 234 on the semiconductor wafer 102. FIG. 4C illustrates a top view of bonding layer 234 on the semiconductor wafer 102. FIG. 4D illustrates a cross-section view of the bonding layer 234 along the line A-A in FIG. 4D.

As shown in FIG. 4C, the bonding layer 234 is formed across the semiconductor wafer 102. As shown in FIG. 4D, in some implementations, another dielectric layer 406 is formed on the semiconductor wafer 102, and the bonding layer 234 is formed on the dielectric layer 406. In some implementations, the dielectric layer 406 is included to provide etch selectivity relative to the bonding layer 234 to enable the bonding layer 234 to be etched for forming the recesses in which the bonding pads 232 are formed.

The electrically insulating material of the bonding layer 234 may include an oxide-containing material such as silicon oxide (SiOₓ such as SiO₂). Additionally and/or alternatively, the electrically insulating material may include another type of dielectric material such as a nitride-containing dielectric material and/or a carbon-containing dielectric material, among other examples.

The bonding layer 234 may be deposited as a “thick” layer in that the bonding layer 234 may be deposited to a thickness (indicated in FIG. 4D as dimension D2) in the micron range. For example, the bonding layer 234 may be deposited to a thickness that is included in a range of approximately 8 microns to approximately 10 microns in a single deposition operation. This enables the bonding layer 234 to be quickly formed to a thickness (dimension D2) such that a top surface of the bonding layer 234 in the edge region 402 of the semiconductor wafer 102 is at a greater vertical (z-direction) height on the semiconductor wafer 102 than a bottom surface of the bonding layer 234 in the non-edge region 404 of the semiconductor wafer 102 by a z-direction distance (indicated in FIG. 4D as dimension D3). This ensures that sufficient material of the bonding layer 234 is deposited in the edge region 402 to enable the sloped surface of the semiconductor wafer 102 in the edge region to be fully filled in with the bonding layer 234, while enabling the bonding layer 234 to be subsequently etched back in the non-edge region 404 to a sufficient thickness for bonding with the semiconductor wafer 104. In some implementations, the bonding layer 234 is formed to a thickness (dimension D2) such that the dimension D3 is included in a range of approximately 3 microns to approximately 5 microns. However, other values and/or ranges for the dimension D2 and the dimension D3 are within the scope of the present disclosure.

To quickly form the bonding layer 234 to a sufficient thickness, a TEOS-CVD deposition technique may be used to deposit the bonding layer 234. This may include using one or more silicon oxide precursors that contain an orthosilicate material such as TEOS and/or another ester of orthosilicate acid to deposit the bonding layer 234. The use of the TEOS-CVD deposition technique may enable the bonding layer 234 to be formed to a sufficient thickness (dimension D2) in a single deposition operation, as opposed to using multiple deposition operations to form the bonding layer 234 to a sufficient thickness using another deposition technique such as HDP-CVD. While this may reduce processing time, cost, and complexity for forming the bonding layer 234, other techniques for forming the bonding layer 234 (such as HPD-CVD) are within the scope of the present disclosure.

The TEOS-CVD deposition technique may include using a deposition tool (e.g., a CVD tool) to provide the silicon oxide precursor(s) onto the top surface of the semiconductor wafer 102, and forming silicon oxide from the silicon oxide precursor(s) by thermal decomposition at a relatively low temperature (e.g., approximately 400 degrees Celsius to approximately 600 degrees Celsius). For example, a TEOS vapor is deposited onto the top surface of the semiconductor wafer such that TEOS is adsorbed onto the top surface of the semiconductor wafer. An oxidizing agent such as oxygen (O₂), ozone (O₃), and/or water (H₂O) is introduced and used to thermally decompose the TEOS to release silicon dioxide (SiO₂) and associated byproducts. An example thermal decomposition may include:

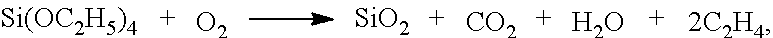

where TEOS (Si(OC₂H₅)) is decomposed by oxygen (O₂) into silicon dioxide (SiO₂) and byproducts such as carbon dioxide (CO₂), water (H₂O), and/or ethylene (C₂H₄). Another example thermal decomposition may include:

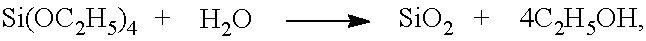

where TEOS (Si(OC₂H₅)) is decomposed by water (H₂O) into silicon dioxide (SiO₂) and byproducts such as ethanol (C₂H₅OH).

As shown in FIGS. 4E and 4F, a photoresist layer 408 is formed over the bonding layer 234 in the edge region 402 and in the non-edge region 404. In other words, the photoresist layer 408 coats the top surface of the semiconductor wafer 102. FIG. 4E illustrates a top view of the photoresist layer 408 on the semiconductor wafer 102. FIG. 4F illustrates a cross-section view of the photoresist layer 408 along the line A-A in FIG. 4E.

A deposition tool may be used to deposit the photoresist layer 408 using a spin-coating technique and/or another suitable deposition technique. As shown in FIG. 4F, a portion of the photoresist layer 408 in the edge region 402 of the semiconductor wafer 102 is exposed to light or another type of electromagnetic radiation to pattern the photoresist layer 408. The photoresist layer 408 may include a negative photoresist material that cross-links and becomes insoluble to developer when exposed to light. Thus, exposing the portion of the photoresist layer 408 in the edge region 402 of the semiconductor wafer 102 to light enables the portion of the photoresist layer 408 to remain in the edge region 402 of the semiconductor wafer 102 after developing. Examples of negative photoresist materials that may be used for the photoresist layer 408 include epoxy-based photoresist materials such as SU-8, NR9-8000PY, and/or S1813, among other examples.

The use of a negative photoresist material for the photoresist layer 408 enables WEE photolithography patterning tools to be used to expose the portion of the photoresist layer 408 in the edge region 402 of the semiconductor wafer 102. However, in other implementations, a positive photoresist material may be used, and the portion of the photoresist layer 408 in the non-edge region 404 of the semiconductor wafer 102 may be exposed to light to pattern the photoresist layer 408.

As shown in FIGS. 4G and 4H, a developer tool may be used to remove the portion of the photoresist layer 408 in the non-edge region 404 of the semiconductor wafer 102 such that the portion of the photoresist layer 408 in the edge region 402 remains on the semiconductor wafer 102. The portion of the photoresist layer 408 that remains in the edge region 402 on the semiconductor wafer 102 corresponds to portion 410a of a blocking layer 410 that is formed in the edge region 402 of the semiconductor wafer 102. FIG. 4G illustrates a top view of blocking layer 410 on the semiconductor wafer 102. FIG. 4H illustrates a cross-section view of the blocking layer 410 along the line A-A in FIG. 4G.

As shown in FIG. 4G, the blocking layer 410 extends around the outer perimeter of the semiconductor wafer 102 in the edge region 402 of the semiconductor wafer 102. As shown in FIG. 4H, the portion 410a of the blocking layer 410 fills in, both laterally (x-direction) and vertically (z-direction), a portion of edge region 402 of the semiconductor wafer 102.

As shown in FIGS. 4I and 4J, another photoresist layer 412 may be formed over the bonding layer 234 in the edge region 402 and in the non-edge region 404. In other words, the photoresist layer 412 coats the top surface of the semiconductor wafer 102. FIG. 4I illustrates a top view of photoresist layer 412 on the semiconductor wafer 102. FIG. 4J illustrates a cross-section view of the photoresist layer 412 along the line A-A in FIG. 4I.

A deposition tool may be used to deposit the photoresist layer 412 using a spin-coating technique and/or another suitable deposition technique. As shown in FIG. 4J, the photoresist layer 412 covers the portion 410a of the blocking layer 410. In other words, the photoresist layer 412 is formed on the portion 410a of the blocking layer 410 in the edge region 402 of the semiconductor wafer 102.

As further shown in FIG. 4J, a portion of the photoresist layer 412 in the edge region 402 of the semiconductor wafer 102 is exposed to light or another type of electromagnetic radiation to pattern the photoresist layer 412. The photoresist layer 412 may include a negative photoresist material that cross-links and becomes insoluble to developer when exposed to light. Thus, exposing the portion of the photoresist layer 412 in the edge region 402 of the semiconductor wafer 102 to light enables the portion of the photoresist layer 412 to remain in the edge region 402 of the semiconductor wafer 102 after developing. The use of a negative photoresist material for the photoresist layer 412 enables WEE photolithography patterning tools to be used to expose the portion of the photoresist layer 412 in the edge region 402 of the semiconductor wafer 102. However, in other implementations, a positive photoresist material may be used, and the portion of the photoresist layer 412 in the non-edge region 404 of the semiconductor wafer 102 may be exposed to light to pattern the photoresist layer 412.

As shown in FIGS. 4K and 4L, a developer tool may be used to remove the portion of the photoresist layer 412 in the non-edge region 404 of the semiconductor wafer 102 such that the portion of the photoresist layer 412 in the edge region 402 remains on the semiconductor wafer 102. The portion of the photoresist layer 412 that remains in the edge region 402 on the semiconductor wafer 102 corresponds to another portion 410b of the blocking layer 410 that is formed in the edge region 402 of the semiconductor wafer 102. FIG. 4K illustrates a top view of blocking layer 410 on the semiconductor wafer 102. FIG. 4L illustrates a cross-section view of the blocking layer 410 along the line A-A in FIG. 4G.

As shown in FIG. 4K, forming the portion 410b of the blocking layer 410 results in the blocking layer 410 occupying a greater amount of lateral area in the edge region 402 around the outer perimeter of the semiconductor wafer 102 than prior to formation of the portion 410b. As shown in FIG. 4L, the portion 410b of the blocking layer 410 fills in, both laterally (x-direction) and vertically (z-direction), a portion of edge region 402 of the semiconductor wafer 102. The portion 410b is formed on the portion 410a of the blocking layer 410 and covers a greater lateral (x-direction) area of the edge region 402 than the portion 410a.

As shown in FIGS. 4M and 4N, another photoresist layer 414 may be formed over the bonding layer 234 in the edge region 402 and in the non-edge region 404. In other words, the photoresist layer 414 coats the top surface of the semiconductor wafer 102. FIG. 4M illustrates a top view of photoresist layer 414 on the semiconductor wafer 102. FIG. 4N illustrates a cross-section view of the photoresist layer 414 along the line A-A in FIG. 4M.

A deposition tool may be used to deposit the photoresist layer 414 using a spin-coating technique and/or another suitable deposition technique. As shown in FIG. 4N, the photoresist layer 414 covers the portions 410a and 410b of the blocking layer 410. In other words, the photoresist layer 414 is formed above and/or on the portions 410a and 410b of the blocking layer 410 in the edge region 402 of the semiconductor wafer 102.

As further shown in FIG. 4N, a portion of the photoresist layer 414 in the edge region 402 of the semiconductor wafer 102 is exposed to light or another type of electromagnetic radiation to pattern the photoresist layer 414. The photoresist layer 414 may include a negative photoresist material that cross-links and becomes insoluble to developer when exposed to light. Thus, exposing the portion of the photoresist layer 414 in the edge region 402 of the semiconductor wafer 102 to light enables the portion of the photoresist layer 414 to remain in the edge region 402 of the semiconductor wafer 102 after developing. The use of a negative photoresist material for the photoresist layer 414 enables WEE photolithography patterning tools to be used to expose the portion of the photoresist layer 414 in the edge region 402 of the semiconductor wafer 102. However, in other implementations, a positive photoresist material may be used, and the portion of the photoresist layer 414 in the non-edge region 404 of the semiconductor wafer 102 may be exposed to light to pattern the photoresist layer 414.

As shown in FIGS. 4O and 4P, a developer tool may be used to remove the portion of the photoresist layer 414 in the non-edge region 404 of the semiconductor wafer 102 such that the portion of the photoresist layer 414 in the edge region 402 remains on the semiconductor wafer 102. The portion of the photoresist layer 414 that remains in the edge region 402 on the semiconductor wafer 102 corresponds to another portion 410a of the blocking layer 410 that is formed in the edge region 402 of the semiconductor wafer 102. FIG. 4O illustrates a top view of blocking layer 410 on the semiconductor wafer 102. FIG. 4P illustrates a cross-section view of the blocking layer 410 along the line A-A in FIG. 4O.

As shown in FIG. 4O, forming the portion 410c of the blocking layer 410 results in the blocking layer 410 occupying approximately the entire lateral area in the edge region 402 around the outer perimeter of the semiconductor wafer 102. As shown in FIG. 4P, the portion 410c of the blocking layer 410 fills in, both laterally (x-direction) and vertically (z-direction), a portion of edge region 402 of the semiconductor wafer 102. The portion 410c is formed on the portion 410b of the blocking layer 410 and covers a greater lateral (x-direction) area of the edge region 402 than each of the portions 410a and 410b.

FIG. 4Q illustrates a detailed cross-section view of the blocking layer 410. As shown in FIG. 4Q, each of the portions 410a-410c of the blocking layer 410 may have a z-direction thickness and an x-direction width. For example, the portion 410a may have a z-direction thickness (dimension D5 in FIG. 4Q) and an x-direction width (dimension D6 in FIG. 4Q), the portion 410b may have a z-direction thickness (dimension D7 in FIG. 4Q) and an x-direction width (dimension D8 in FIG. 4Q), the portion 410c may have a z-direction thickness (dimension D9 in FIG. 4Q) and an x-direction width (dimension D10 in FIG. 4Q), and so on.

In some implementations, the z-direction thicknesses of each of the portions 410a-410c (e.g., the dimensions D5, D7, and D9) may be approximately the same thickness (e.g., within approximately 5% variation, within approximately 10% variation). In some implementations, the z-direction thicknesses of two or more of the portions 410a-410c (e.g., of two or more of the dimensions D5, D7, and D9) may be different thicknesses.

The combination of the z-direction thicknesses of each of the portions 410a-410c (e.g., the dimensions D5, D7, and D9) may result in the blocking layer 410 having an overall z-direction thickness such that the top surface of the blocking layer 410 is at approximately a same z-direction height in the semiconductor wafer 102 as the top surface of the bonding layer 234. Alternatively, the top surface of the blocking layer 410 may extend above the top surface of the bonding layer 234 in the non-edge region 404 by a distance (indicated in FIG. 4Q as dimension D11). This may increase the likelihood that the blocking layer 410 is not fully consumed during a subsequent etch-back operation before etching of the bonding layer 234 is completed in the etch-back operation.

The x-direction widths of each of the portions 410a-410c (e.g., the dimensions D6, D8, and D10) may be based on the x-direction cross-sectional profile of the edge region 402 of the semiconductor wafer 102 because each of the portions 410a-410c conforms to the x-direction cross-sectional profile of the edge region 402. However, in implementations in which the top surface of the bonding layer 234 slopes downward toward the outer edge of the semiconductor wafer 102 due to edge roll-off in the edge region 402, the x-direction widths of the portions at top of the blocking layer 410 may be greater than the x-direction widths of the portions at the bottom of the blocking layer 410. For example, the x-direction width of the portion 410b (e.g., the dimension D8) may be greater than the x-direction width of the portion 410a (e.g., the dimension D6), and the x-direction width of the portion 410c (e.g., the dimension D10) may be greater than the x-direction width of the portion 410d (e.g., the dimension D8).

The example quantity of portions 410a-410c of the blocking layer 410, and the associated dimensions of the portions 410a-410c are examples, and other quantities of portions and associated dimensions of those portions are within the scope of the present disclosure. For example, the sequence of operations described in connection with FIGS. 4E-4P may be expanded to include formation of a greater quantity of portions (e.g., 4 portions, 6 portions, 10 portions) for the blocking layer 410. As another example, the sequence of operations described in connection with FIGS. 4E-4P may be reduced to include two portions for the blocking layer 410. In some implementations, only the operations described in connection with FIGS. 4E-4H are performed to form the blocking layer 410 (e.g., a single portion for the blocking layer 410) from the photoresist layer 408.

In some implementations, the quantity of portions that are included in the blocking layer 410 is based on an amount of edge roll-off (dimension D1) in the edge region 402 of the semiconductor wafer 102. For example, greater quantities of portions may be formed for the blocking layer 410 for greater amounts of edge roll-off, and lesser quantities of portions may be formed for the blocking layer 410 for lesser amounts of edge roll-off. This is to ensure that each portion that is formed is fully exposed and cross-linked, and to reduce the likelihood of under-exposure of the portions of the blocking layer 410.

In some implementations, the quantity of portions that are included in the blocking layer 410 is based on a capability of the exposure tool (e.g., the WEE tool) that is used to pattern the photoresist layers from which the portions of the blocking layer 410 are formed. For example, if the exposure tool is capable of exposing and patterning thicker photoresist layers, then lesser quantities of portions may be used for the blocking layer 410 for the same amount of edge roll-off than if another exposure tool that is capable of exposing and patterning photoresist layers of lesser thicknesses were used to form the blocking layer 410.

In some implementations, the quantity of portions that are included in the blocking layer 410 is based on the type of etchant that is used to etch the bonding layer 234 in an etch-back operation described in connection with FIG. 4R. A greater quantity of portions may be formed for the blocking layer 410 to form the blocking layer 410 to a greater overall z-direction thickness where the bonding layer 234 is etched using an etchant that has a greater etch rate for the blocking layer 410 than for the bonding layer 234. Conversely, fewer portions may be formed for the blocking layer 410 to form the blocking layer 410 to a lesser overall z-direction thickness where the bonding layer 234 is etched using an etchant that has a greater etch rate for the bonding layer 234 than for the blocking layer 410.

As shown in FIG. 4R, an etch-back operation is performed to etch the bonding layer 234 based on the blocking layer 410. An etch tool may be used to perform the etch-back operation to thin the bonding layer 234 (e.g., to reduce the thickness of the bonding layer 234). The etch-back operation may include the use of a dry etch technique (e.g., a plasma-based etch technique, a gas-based etch technique), a wet etch technique (e.g., a chemical etch technique), and/or another type of etch technique.

As shown in FIG. 4R, the blocking layer 410 is consumed as the bonding layer 234 is etched during the etch-back operation. An etchant is used that has low to no etch selectivity between the material of the bonding layer 234 (e.g., silicon dioxide (SiO₂)) and the material of the blocking layer 410 (e.g., an epoxy-based material). Thus, the material is removed from the blocking layer 410 has a similar etch rate as the material of the bonding layer 234. At the completion of the etch-back operation, the blocking layer 410 is fully removed from the edge region 402 of the semiconductor wafer 102. This prevents, minimizes, and/or reduces the likelihood of cross-contamination of materials on the semiconductor wafer 102 that might otherwise result during a subsequent planarization operation to planarize the bonding layer 234. The etch-back operation may be stopped once the blocking layer 410 is fully removed from the edge region 402 of the semiconductor wafer 102. Alternatively, the etch-back operation may continue after the blocking layer 410 is fully removed from the edge region 402 of the semiconductor wafer 102 to ensure that the blocking layer 410 is fully removed. In these implementations, a portion of the bonding layer 234 in the edge region 402 is also removed from the semiconductor wafer 102. For example, if the thickness of the blocking layer is approximately 8 microns, the etch-back operation may be performed to remove approximately 8.5 microns of material from the edge region 402 of the semiconductor wafer 102. However, other values are within the scope of the present disclosure.

In other implementations, a portion of the blocking layer 410 may remain on the semiconductor wafer 102 in the edge region, and another technique such as ashing or chemical stripping is used to remove the remaining portion of the blocking layer 410.

As further shown in FIG. 4R, at the completion of the etch-back operation, the top surface of the bonding layer 234 in the edge region 402 of the semiconductor wafer 102 and the top surface of the bonding layer 234 in the non-edge region 404 of the semiconductor wafer 102 may be approximately co-planar. Alternatively, the top surface of the bonding layer 234 in the edge region 402 of the semiconductor wafer 102 may be located at a higher vertical position (e.g., a higher z-direction height) in the semiconductor wafer 102 than the top surface of the bonding layer 234 in the non-edge region 404 of the semiconductor wafer 102. This may occur due to the blocking layer 410 being formed such that the top surface of the blocking layer 410 extends above the top surface of the bonding layer 234 in the non-edge region 404 by a distance (dimension D11), as described in connection with FIG. 4Q.

As shown in FIGS. 4S and 4T, a planarization tool may be used to perform a planarization operation (e.g., a CMP operation) to planarize the top surface of the bonding layer 234 after the etch-back operation. FIG. 4S illustrates a top view of bonding layer 234 after the planarization operation. FIG. 4T illustrates a cross-section view of the bonding layer 234 along the line A-A in FIG. 4S. As shown in FIG. 4T, the top surface of the bonding layer 234 in the edge region 402 of the semiconductor wafer 102 and the top surface of the bonding layer 234 in the non-edge region 404 of the semiconductor wafer 102 may be approximately co-planar after the planarization operation. The planarization operation may be performed to reduce variation in the thickness of the bonding layer 234 across the non-edge region 404 of the semiconductor wafer 102.

As shown in FIG. 4U, the bonding layer 234 in the non-edge region 404 of the semiconductor wafer 102 may have a thickness (indicated in FIG. 4U as dimension D12) after the planarization operation that is less than a thickness (indicated in FIG. 4U as dimension D13) of the bonding layer 234 in the edge region 402 of the semiconductor wafer 102 after the planarization operation. The difference in thicknesses of bonding layer 234 in the edge region 402 and in the non-edge region 404 results from the blocking layer 410 protecting the bonding layer 234 in the edge region 402 during the etch-back operation described in connection with FIG. 4R. The greater thickness of the bonding layer 234 in the edge region 402 than in the non-edge region 404 also occurs because of the bonding layer 234 filling in the slope (e.g., the edge roll-off) in the edge region 402 of the semiconductor wafer 102.

In some implementations, a small amount of slope or edge roll-off (indicated in FIG. 4U as dimension D14) may remain in the edge region 402 after the planarization operation. However, the small amount of slope or edge roll-off may have minimal impact on the bonding performance for bonding the semiconductor wafer 102 with the semiconductor wafer 104. In some implementations, the amount of remaining slope or edge roll-off is less than the thickness of the bonding layer 234 in the non-edge region 404 after the planarization operation.

As indicated above, FIGS. 4A-4U are provided as an example. Other examples may differ from what is described with regard to FIGS. 4A-4U.

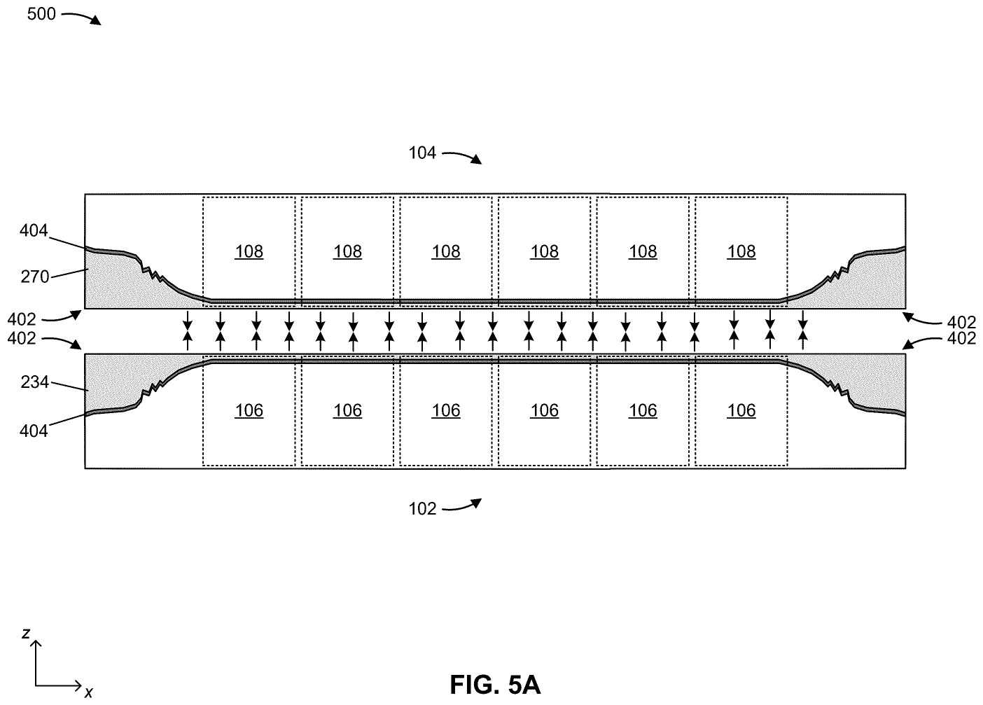

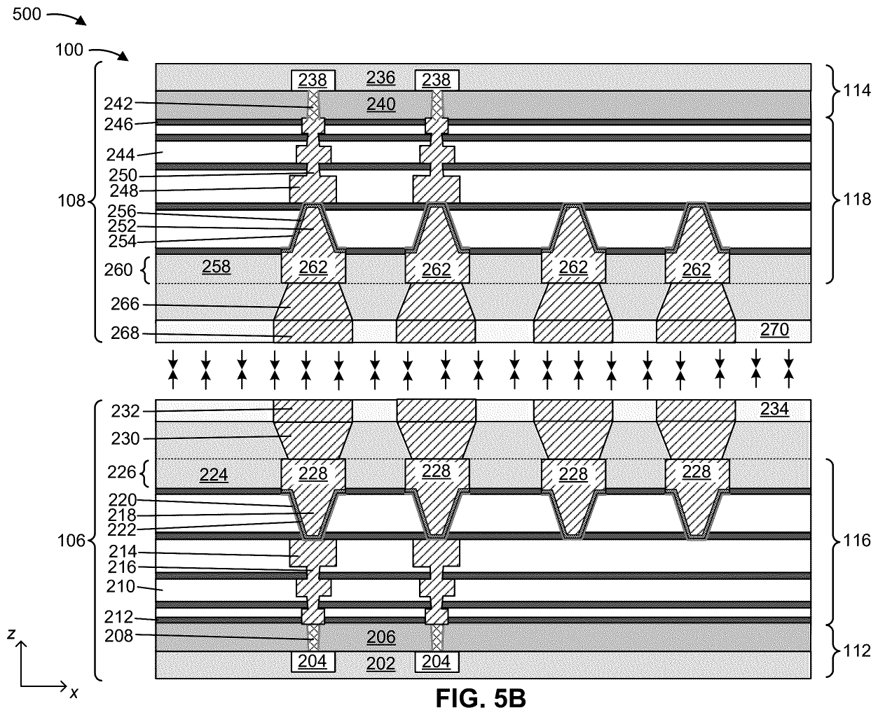

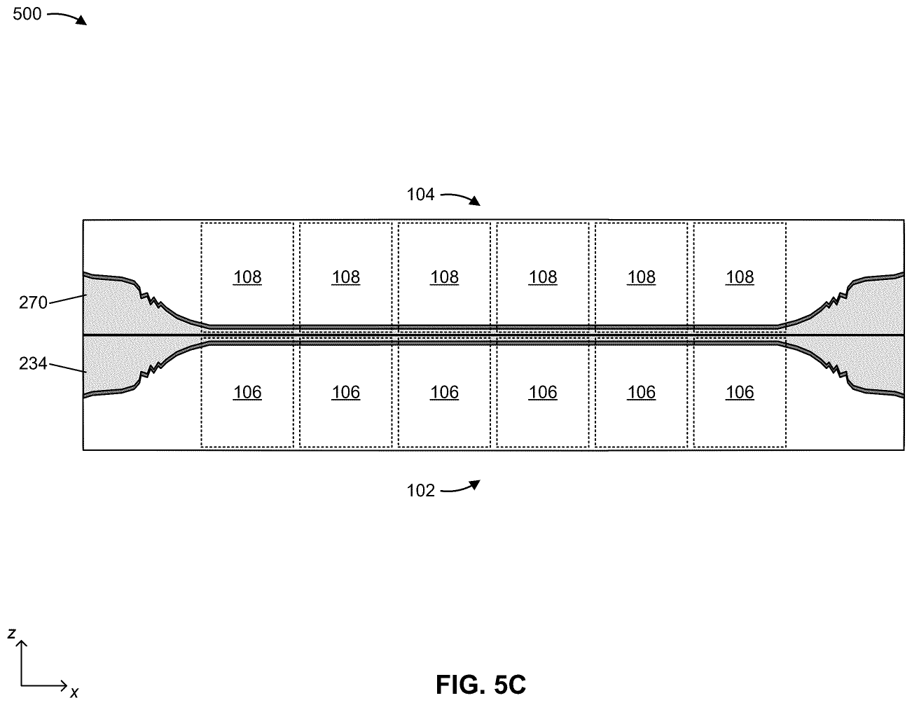

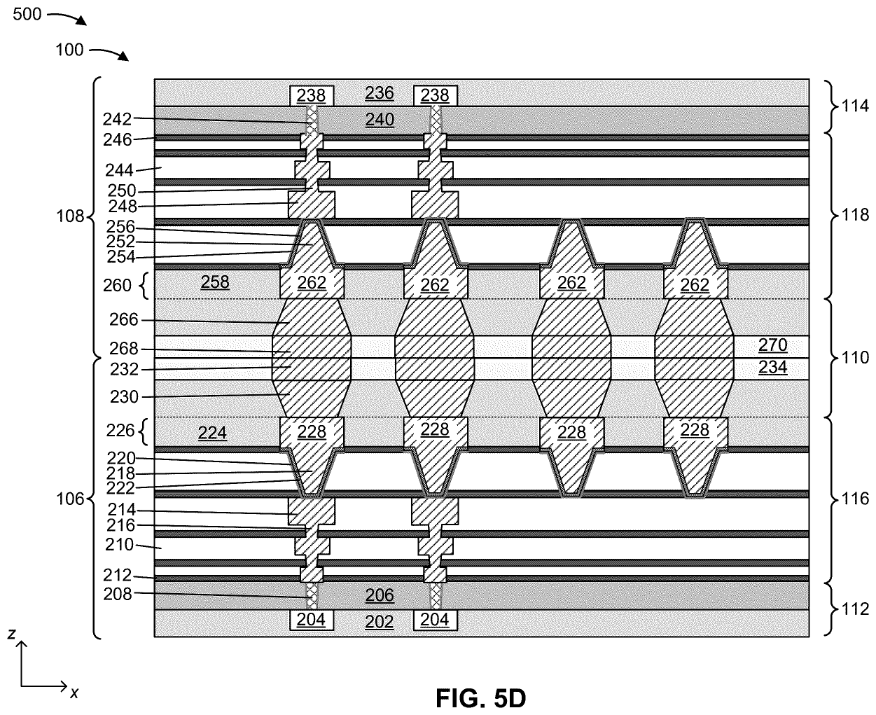

FIGS. 5A-5D are diagrams of an example implementation 500 of forming a semiconductor device 100 described herein. In particular, the example implementation 500 includes an example of bonding the semiconductor die 106 and the semiconductor die 108 to form the semiconductor device 100.

As shown in FIG. 5A, the semiconductor wafer 102 and the semiconductor wafer 104 may be positioned such that the bonding layer 234 on the semiconductor wafer 102 and the bonding layer 270 on the semiconductor wafer 104 are facing each other. As further shown in FIG. 5A, the semiconductor wafer 102 and the semiconductor wafer 104 may be positioned such that the semiconductor dies 106 on the semiconductor wafer 102 and the semiconductor dies 106 on the semiconductor wafer 104 are aligned.

As shown in FIG. 5B, a semiconductor die 106 on the semiconductor wafer 102 and a semiconductor die 108 on the semiconductor wafer 104 may be aligned for bonding. The semiconductor die 106 and the semiconductor die 108 may be positioned such that the bonding pads 232 on the semiconductor die 106 and the bonding pads 268 on the semiconductor die 108 are facing each other and are approximately aligned in the z-direction.

As shown in FIG. 5C, the bonding operation includes bonding the semiconductor wafer 102 and the semiconductor wafer 104 such that the bonding layer 234 and the bonding layer 270 are bonded together in the edge regions 402 and in the non-edge regions 404 of the semiconductor wafer 102 and the semiconductor wafer 104. As further shown in FIG. 5C, the techniques described in connection with FIGS. 4A-4U that are used to rebuild the edge of the semiconductor wafer 102 and/or to rebuild the edge of the semiconductor wafer 104 enable the bonding layer 234 and bonding layer 270 to be fully bonded across the semiconductor wafers 102 and 104.

As shown in FIG. 5D, the bonding operation results in a semiconductor die 106 and a semiconductor die 106 being bonded at a bonding interface 110 such that the semiconductor die 106 and the semiconductor die 108 are vertically arranged or stacked in the z-direction in the semiconductor device 100. The semiconductor die 106 and the semiconductor die 108 may be vertically arranged or stacked in a wafer-on-wafer (WoW) configuration, a die-on-wafer configuration, a die-on-die configuration, and/or another direct bonding configuration. A bonding tool may be used to perform the bonding operation to bond the semiconductor die 106 and the semiconductor die 108 at the bonding interface 110. The bonding operation may include forming a direct bond between the semiconductor die 106 and the semiconductor die 108 through a direct physical connection of the bonding pads 232 of the semiconductor die 106 with the bonding pads 268 of the semiconductor die 108, and through a direct physical connection of the bonding layer 234 of the semiconductor die 106 with bonding layer 270 of the semiconductor die 108.

As further shown in FIG. 5D, the techniques described in connection with FIGS. 4A-4U that are used to rebuild the edge of the semiconductor wafer 102 and/or to rebuild the edge of the semiconductor wafer 104 enable the bonding layer 234 and bonding layer 270 to be fully bonded across the bonding interface 110 between opposing edges of the semiconductor device 100.

As indicated above, FIGS. 5A-5D are provided as an example. Other examples may differ from what is described with regard to FIGS. 5A-5D.

FIGS. 6A-6F are diagrams of an example implementation 600 of an edge rebuilding process described herein. The edge rebuilding process may be performed to build up an edge region of a semiconductor wafer. While the example implementation 600 is illustrated and described in connection with the semiconductor wafer 102, the process techniques of the example implementation 600 may be performed for rebuilding the edge of the semiconductor wafer 104. Alternatively, the process techniques of the example implementation 400 may be performed for rebuilding the edge of an individual semiconductor die 106 and/or for an individual semiconductor die 108 for die-to-wafer bonding or for die-to-die bonding.

As shown in FIGS. 6A-6F, the example implementation 600 of the edge rebuilding process is similar to the edge rebuilding process illustrated and described in connection with FIGS. 4A-4U. However, in the example implementation 600, one or more semiconductor dies 106 formed on the semiconductor wafer 102 are at least partially located in the edge region 402 of the semiconductor wafer 102. As a result, at least a portion of the slope (or edge roll-off) of the semiconductor wafer 102 in the edge region 402 occurs in the one or more semiconductor dies 106.

The one or more semiconductor dies 106 that are at least partially located in the edge region 402 of the semiconductor wafer 102 may be referred to as edge dies. As shown in FIGS. 6A and 6B, the bonding layer 234 may be deposited on the semiconductor wafer 102. As shown in FIGS. 6C and 6D, the blocking layer 410 may be formed on the bonding layer 234 in the edge region 402 such that the blocking layer 410 is at least partially formed over the edge dies. As shown in FIGS. 6E and 6F, the blocking layer 410 enables the bonding layer 234 to be etched back and planarized such that the top surface of the bonding layer 234 over the edge dies is approximately co-planar with the top surface of the semiconductor dies 106 in the non-edge region 404 of the semiconductor wafer 102. The blocking layer 410 is fully removed from above the edge dies.

As indicated above, FIGS. 6A-6F are provided as an example. Other examples may differ from what is described with regard to FIGS. 6A-6F.

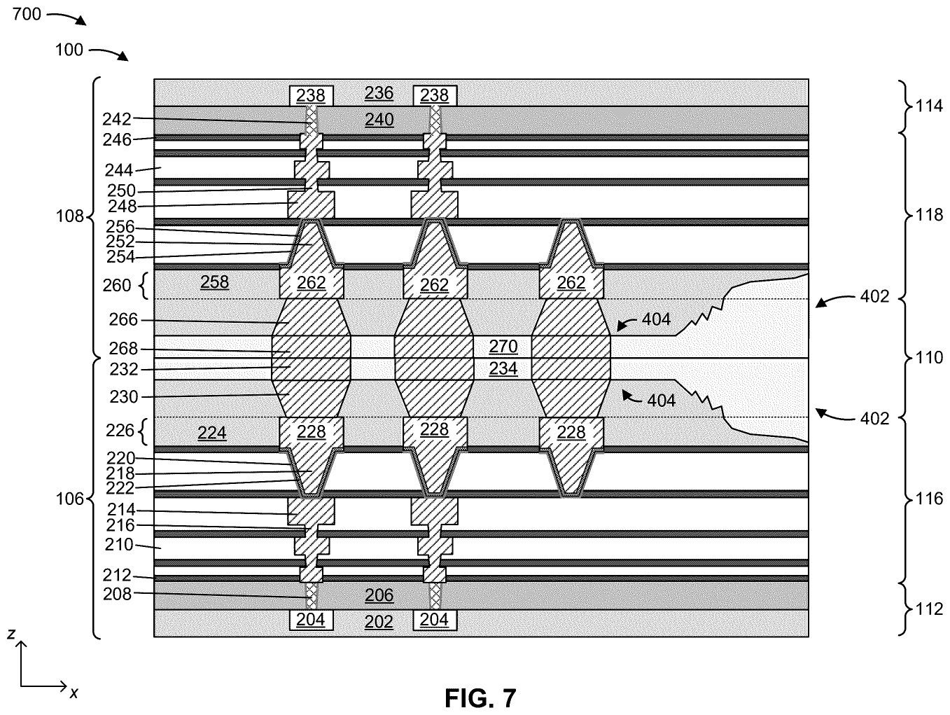

FIG. 7 is a diagram of an example 700 of a semiconductor device 100 described herein. As shown in FIG. 7, the example 700 of the semiconductor device 100 is similar to the example 200 of the semiconductor device illustrated in FIG. 2A. However, in the example 700, the semiconductor device 100 includes a semiconductor die 106 in which a bonding layer 234 has a non-uniform thickness across the bonding interface 110, and/or includes a semiconductor die 108 in which a bonding layer 270 has a non-uniform thickness across the bonding interface 110.

The semiconductor die 106 is located at least partially in the edge region 402 of the semiconductor wafer 102, as described in connection with FIGS. 6A-6F. Thus, the bonding layer 234 may have a greater thickness on one side of the semiconductor die 106 (e.g., the side that was located in the edge region 402 of the semiconductor wafer 102) than the thickness of the bonding layer 234 in a center of the semiconductor die 106 and at an opposing side of the semiconductor die 106 (e.g., which were located in the non-edge region 404 of the semiconductor wafer 102).

Additionally and/or alternatively, the semiconductor die 108 is located at least partially in the edge region 402 of the semiconductor wafer 104. Thus, the bonding layer 270 may have a greater thickness on one side of the semiconductor die 108 (e.g., the side that was located in the edge region 402 of the semiconductor wafer 104) than the thickness of the bonding layer 270 in a center of the semiconductor die 108 and at an opposing side of the semiconductor die 108 (e.g., which were located in the non-edge region 404 of the semiconductor wafer 104).

The techniques described in connection with FIGS. 6A-6F that are used to rebuild the edge of the semiconductor wafer 102 and/or to rebuild the edge of the semiconductor wafer 104 enable the bonding layer 234 and bonding layer 270 to be fully bonded across the bonding interface 110 between opposing edges of the semiconductor device 100.

As indicated above, FIG. 7 is provided as an example. Other examples may differ from what is described with regard to FIG. 7.

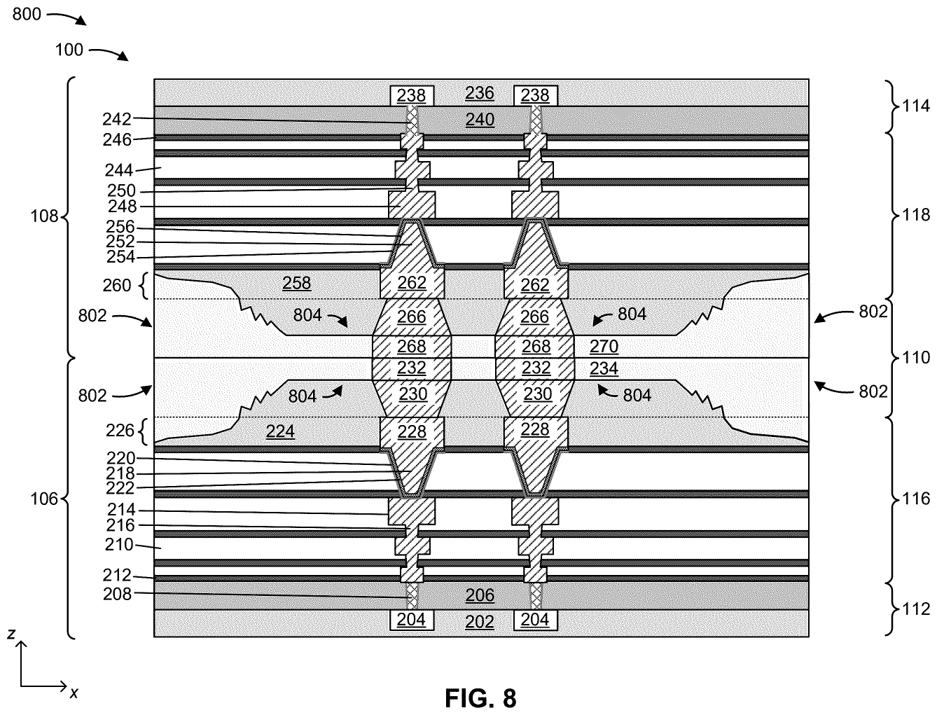

FIG. 8 is a diagram of an example 800 of a semiconductor device 100 described herein. As shown in FIG. 8, the example 800 of the semiconductor device 100 is similar to the example 700 of the semiconductor device illustrated in FIG. 7. However, in the example 800, the semiconductor device 100 includes a semiconductor die 106 in which a bonding layer 234 has a greater thickness in an edge region 802 around the perimeter of the semiconductor die 106 than the thickness of the bonding layer 234 in the non-edge region 804 of the semiconductor die 106. Thus, the thickness of the bonding layer 234 on opposing sides of the semiconductor die 106 is greater than the thickness of the bonding layer 234 at a center of the semiconductor die 106. This may result from the semiconductor die 106 being individually manufactured such that the edge region 802 around the perimeter of the semiconductor die 106 is rebuilt using techniques described in connection with FIGS. 4A-4U.

Additionally and/or alternatively, the semiconductor device 100 includes a semiconductor die 108 in which a bonding layer 270 has a greater thickness in an edge region 802 around the perimeter of the semiconductor die 108 than the thickness of the bonding layer 270 in the non-edge region 804 of the semiconductor die 108. Thus, the thickness of the bonding layer 270 on opposing sides of the semiconductor die 108 is greater than the thickness of the bonding layer 270 at a center of the semiconductor die 108. This may result from the semiconductor die 108 being individually manufactured such that the edge region 802 around the perimeter of the semiconductor die 108 is rebuilt using techniques described in connection with FIGS. 4A-4U.

As indicated above, FIG. 8 is provided as an example. Other examples may differ from what is described with regard to FIG. 8.

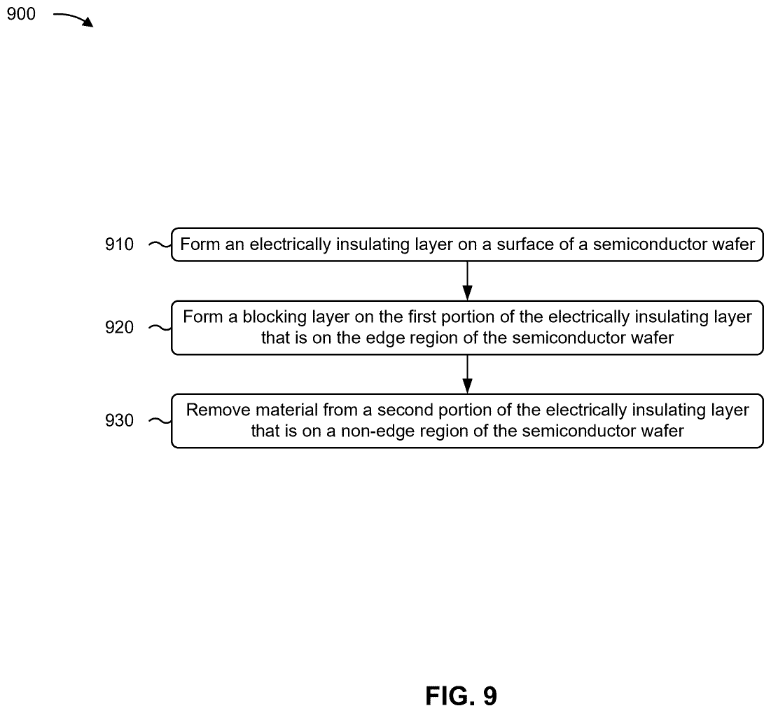

FIG. 9 is a flowchart of an example process 900 associated with rebuilding an edge region of a semiconductor wafer described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, a bonding tool, and/or another type of semiconductor processing tool.

As shown in FIG. 9, process 900 may include forming an electrically insulating layer on a surface of a semiconductor wafer (block 910). For example, one or more semiconductor processing tools may be used to form an electrically insulating layer (e.g., a bonding layer 234) on a surface of a semiconductor wafer (e.g., a semiconductor wafer 102), as described herein. In some implementations, a first portion of the electrically insulating layer is formed on an edge region (e.g., an edge region 402) of the semiconductor wafer.

As further shown in FIG. 9, process 900 may include forming a blocking layer on the first portion of the electrically insulating layer that is on the edge region of the semiconductor wafer (block 920). For example, one or more semiconductor processing tools may be used to form a blocking layer (e.g., a blocking layer 410) on the first portion of the electrically insulating layer that is on the edge region of the semiconductor wafer, as described herein. In some implementations, the blocking layer includes a photoresist material.

As further shown in FIG. 9, process 900 may include removing material from a second portion of the electrically insulating layer that is on a non-edge region of the semiconductor wafer (block 930). For example, one or more semiconductor processing tools may be used to remove material from a second portion of the electrically insulating layer that is on a non-edge region (e.g., a non-edge region 404) of the semiconductor wafer, as described herein. In some implementations, the blocking layer protects the first portion of the electrically insulating layer while the material is removed from the second portion of the electrically insulating layer.

Process 900 may include additional implementations, such as any single implementation or any combination of implementations described below and/or in connection with one or more other processes described elsewhere herein.

In a first implementation, forming the electrically insulating layer includes forming the electrically insulating layer such that a top surface of the first portion of the electrically insulating layer is at a greater vertical (z-direction) height, relative to a top surface of the semiconductor wafer, than a bottom surface of the second portion of the electrically insulating layer.

In a second implementation, alone or in combination with the first implementation, forming the electrically insulating layer comprises forming the electrically insulating layer using a precursor that contains an orthosilicate material.

In a third implementation, alone or in combination with one or more of the first and second implementations, the top surface of the first portion of the electrically insulating layer and a top surface of the second portion of the electrically insulating layer are approximately co-planar after removal of the material of the second portion of the electrically insulating layer.

In a fourth implementation, alone or in combination with one or more of the first through third implementations, the photoresist material of the blocking layer includes a negative photoresist material.

In a fifth implementation, alone or in combination with one or more of the first through fourth implementations, the forming blocking layer includes forming the blocking layer such that a top surface of the blocking layer is approximately co-planar with, or a greater vertical (z-direction) height than, a top surface of the second portion of the electrically insulating layer.

In a sixth implementation, alone or in combination with one or more of the first through fifth implementations, removing the material from the second portion of the electrically insulating layer includes etching the second portion of the electrically insulating layer, and planarizing the second portion of the electrically insulating layer after etching the second portion of the electrically insulating layer.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

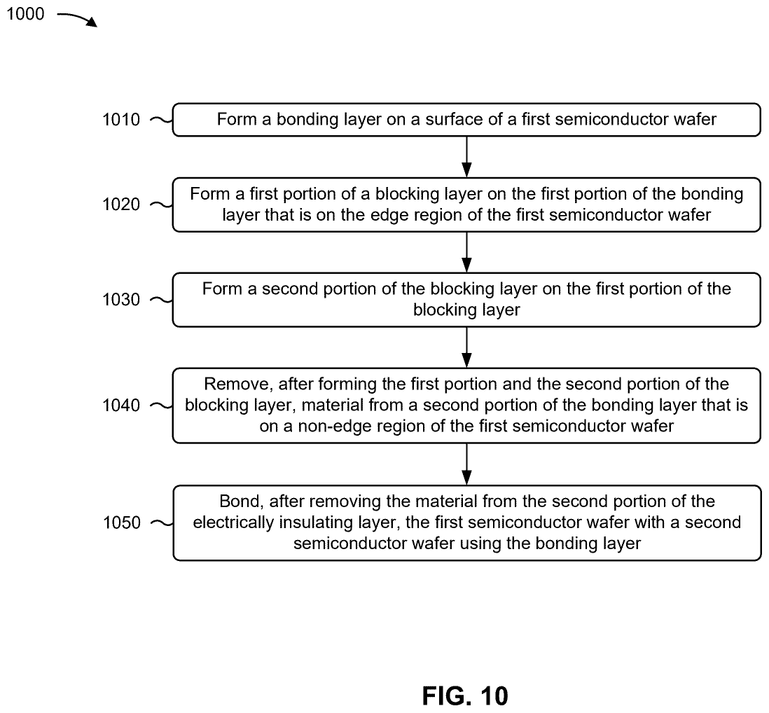

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a bonding layer on a surface of a first semiconductor wafer (block 1010). For example, one or more semiconductor processing tools may be used to form a bonding layer (e.g., a bonding layer 234) on a surface of a first semiconductor wafer (e.g., a semiconductor wafer 102), as described herein. In some implementations, a first portion of the bonding layer is formed on an edge region (e.g., an edge region 402) of the first semiconductor wafer.

As further shown in FIG. 10, process 1000 may include forming a first portion of a blocking layer on the first portion of the bonding layer that is on the edge region of the first semiconductor wafer (block 1020). For example, one or more semiconductor processing tools may be used to form a first portion (e.g., a portion 410a, a portion 410b) of a blocking layer (e.g., a blocking layer 410) on the first portion of the bonding layer that is on the edge region of the first semiconductor wafer, as described herein. In some implementations, the first portion of the blocking layer fills in a first portion of edge region. In some implementations, the blocking layer includes an epoxy-based material.

As further shown in FIG. 10, process 1000 may include forming a second portion of the blocking layer on the first portion of the blocking layer (block 1030). For example, one or more semiconductor processing tools may be used to form a second portion (e.g., a second portion 410b, a second portion 410c) of the blocking layer on the first portion of the blocking layer, as described herein. In some implementations, the second portion of the blocking layer fills in a second portion of the edge region.

As further shown in FIG. 10, process 1000 may include removing, after forming the first portion and the second portion of the blocking layer, material from a second portion of the bonding layer that is on a non-edge region of the first semiconductor wafer (block 1040). For example, one or more semiconductor processing tools may be used to remove, after forming the first portion and the second portion of the blocking layer, material from a second portion of the bonding layer that is on a non-edge region (e.g., a non-edge region 404) of the first semiconductor wafer, as described herein. In some implementations, the blocking layer protects the first portion of the bonding layer while the material is removed from the second portion of the bonding layer. In some implementations, a thickness (e.g., a dimension D13) of the first portion of the bonding layer is greater than a thickness (e.g., a dimension D12) of the second portion of the bonding layer after removing the material from the second portion of the bonding layer.

As further shown in FIG. 10, process 1000 may include bonding, after removing the material from the second portion of the bonding layer, the first semiconductor wafer with a second semiconductor wafer using the bonding layer (block 1050). For example, one or more semiconductor processing tools may be used to bond, after removing the material from the second portion of the bonding layer, the first semiconductor wafer with a second semiconductor wafer (e.g., a second semiconductor wafer 104) after removing the material from the second portion of the bonding layer, as described herein.

Process 1000 may include additional implementations, such as any single implementation or any combination of implementations described below and/or in connection with one or more other processes described elsewhere herein.

In a first implementation, the blocking layer is fully removed from the edge region of the first semiconductor wafer during removal of the material from the second portion of the bonding layer.

In a second implementation, alone or in combination with the first implementation, removing the material from the second portion of the bonding layer includes etching the second portion of the bonding layer, and planarizing the second portion of the bonding layer after etching the second portion of the bonding layer, wherein the blocking layer is fully removed from the edge region of the first semiconductor wafer during the etching of the second portion of the bonding layer.

In a third implementation, alone or in combination with one or more of the first and second implementations, a first lateral width (e.g., a dimension D6) of the first portion of the blocking layer is less than a second lateral width (e.g., a dimension D8) of the second portion of the blocking layer.

In a fourth implementation, alone or in combination with one or more of the first through third implementations, forming the first portion of the blocking layer includes depositing a photoresist layer (e.g., a photoresist layer 408, a photoresist layer 412) over the first semiconductor wafer, exposing a first portion of the photoresist layer, in the edge region, to radiation, and removing a second portion of the photoresist layer after exposing the first portion of the photoresist layer to the radiation, wherein the first portion of the photoresist layer corresponds to the first portion of the blocking layer.

In a fifth implementation, alone or in combination with one or more of the first through fourth implementations, forming the second portion of the blocking layer includes depositing another photoresist layer (e.g., a photoresist layer 412, a photoresist layer 414) over the first semiconductor wafer, exposing a first portion of the other photoresist layer, in the edge region, to radiation, and removing a second portion of the other photoresist layer after exposing the first portion of the other photoresist layer to the radiation, wherein the first portion of the other photoresist layer corresponds to the second portion of the blocking layer.

In a sixth implementation, alone or in combination with one or more of the first through fifth implementations, process 1000 includes forming a third portion (e.g., a portion 410c) of the blocking layer on the second portion of the blocking layer, wherein the third portion of the blocking layer fills in a third portion of the edge region, and wherein removing the material from the second portion of the bonding layer comprises removing the material from the second portion of the bonding layer after forming the third portion of the blocking layer.

In a seventh implementation, alone or in combination with one or more of the first through sixth implementations, a first lateral width (e.g., a dimension D8) of the second portion of the blocking layer is less than a second lateral width (e.g., a dimension D10) of the third portion of the blocking layer.

In an eighth implementation, alone or in combination with one or more of the first through seventh implementations, forming the bonding layer includes forming the first bonding layer using a precursor that contains an ester of orthosilicate acid.

In a ninth implementation, alone or in combination with one or more of the first through eighth implementations, forming the bonding layer comprises forming the first bonding layer using a precursor that contains tetraethyl orthosilicate (TEOS).

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a thick bonding layer is formed over a surface of a semiconductor wafer such that a top surface of the bonding layer in an edge region (which may have edge roll-off) is at a greater vertical height than a bottom surface of the bonding layer in a non-edge region of the semiconductor wafer. A photoresist material is then deposited across the surface of the semiconductor wafer and patterned such that the photoresist material remains only on the edge region of the semiconductor wafer. The photoresist material is used to etch the bonding layer. Forming the bonding layer such that the top surface of the bonding layer in the edge region is at a greater vertical height than the bottom surface of the bonding layer in the non-edge region of the semiconductor wafer enables the bonding layer in the non-edge region to be etched based on the photoresist material such that the top surface of the bonding layer is substantially flat and uniform across the edge region and the non-edge region of the semiconductor wafer. In other words, the bonding layer is formed to a sufficient thickness in the edge region to enable the bonding layer to be thinned in the non-edge region such that little to no slope in the edge region remains after the bonding layer is etched.

As described in greater detail above, some implementations described herein provide a method. The method includes forming an electrically insulating layer on a surface of a semiconductor wafer, where a first portion of the electrically insulating layer is formed on an edge region of the semiconductor wafer. The method includes forming a blocking layer on the first portion of the electrically insulating layer that is on the edge region of the semiconductor wafer, where the blocking layer comprises a photoresist material. The method includes removing material from a second portion of the electrically insulating layer that is on a non-edge region of the semiconductor wafer, where the blocking layer protects the first portion of the electrically insulating layer while the material is removed from the second portion of the electrically insulating layer.

As described in greater detail above, some implementations described herein provide a method. The method includes forming a bonding layer on a surface of a first semiconductor wafer, where a first portion of the bonding layer is formed on an edge region of the first semiconductor wafer. The method includes forming a first portion of a blocking layer on the first portion of the bonding layer that is on the edge region of the first semiconductor wafer, where the first portion of the blocking layer fills in a first portion of edge region. The method includes forming a second portion of the blocking layer on the first portion of the blocking layer, where the second portion of the blocking layer fills in a second portion of the edge region. The method includes removing, after forming the first portion and the second portion of the blocking layer, material from a second portion of the bonding layer that is on a non-edge region of the first semiconductor wafer, where the blocking layer protects the first portion of the bonding layer while the material is removed from the second portion of the bonding layer, and where a thickness of the first portion of the bonding layer is greater than a thickness of the second portion of the bonding layer after removing the material from the second portion of the bonding layer. The method includes bonding, after removing the material from the second portion of the bonding layer, the first semiconductor wafer with a second semiconductor wafer using the bonding layer.

As described in greater detail above, some implementations described herein provide a semiconductor device. The semiconductor device includes a first semiconductor die. The semiconductor device includes a second semiconductor die bonded with the first semiconductor die at a bonding interface such that the first semiconductor die and the second semiconductor die are vertically arranged in the semiconductor device. The bonding interface includes a first bonding layer of the first semiconductor die that is directly bonded with a second bonding layer of the second semiconductor die. At least one of the first bonding layer or the second bonding layer has a non-uniform thickness across the bonding interface. The first bonding layer and the second bonding layer are fully bonded across the bonding interface between opposing edges of the semiconductor device.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an electrically insulating layer on a surface of a semiconductor wafer,
wherein a first portion of the electrically insulating layer is formed on an edge region of the semiconductor wafer;
forming a blocking layer on the first portion of the electrically insulating layer that is on the edge region of the semiconductor wafer,
wherein the blocking layer comprises a photoresist material; and
removing material from a second portion of the electrically insulating layer that is on a non-edge region of the semiconductor wafer,
wherein the blocking layer protects the first portion of the electrically insulating layer while the material is removed from the second portion of the electrically insulating layer.

2. The method of claim 1, wherein forming the electrically insulating layer comprises:
forming the electrically insulating layer such that a top surface of the first portion of the electrically insulating layer is at a greater vertical height, relative to a top surface of the semiconductor wafer, than a bottom surface of the second portion of the electrically insulating layer.

3. The method of claim 2, wherein forming the electrically insulating layer comprises forming the electrically insulating layer using a precursor that contains an orthosilicate material.

4. The method of claim 2, wherein the top surface of the first portion of the electrically insulating layer and a top surface of the second portion of the electrically insulating layer are approximately co-planar after removal of the material of the second portion of the electrically insulating layer.

5. The method of claim 1, wherein the photoresist material of the blocking layer comprises a negative photoresist material.

6. The method of claim 1, wherein the forming blocking layer comprises:
forming the blocking layer such that a top surface of the blocking layer is approximately co-planar with, or a greater vertical height than, a top surface of the second portion of the electrically insulating layer.

7. The method of claim 1, wherein removing the material from the second portion of the electrically insulating layer comprises:
etching the second portion of the electrically insulating layer; and
planarizing the second portion of the electrically insulating layer after etching the second portion of the electrically insulating layer.

8. A method, comprising:
forming a bonding layer on a surface of a first semiconductor wafer,
wherein a first portion of the bonding layer is formed on an edge region of the first semiconductor wafer;
forming a first portion of a blocking layer on the first portion of the bonding layer that is on the edge region of the first semiconductor wafer,
wherein the first portion of the blocking layer fills in a first portion of edge region;
forming a second portion of the blocking layer on the first portion of the blocking layer,
wherein the second portion of the blocking layer fills in a second portion of the edge region;
removing, after forming the first portion and the second portion of the blocking layer, material from a second portion of the bonding layer that is on a non-edge region of the first semiconductor wafer,
wherein the blocking layer protects the first portion of the bonding layer while the material is removed from the second portion of the bonding layer, and
wherein a thickness of the first portion of the bonding layer is greater than a thickness of the second portion of the bonding layer after removing the material from the second portion of the bonding layer; and
bonding, after removing the material from the second portion of the bonding layer, the first semiconductor wafer with a second semiconductor wafer using the bonding layer.

9. The method of claim 8, wherein the blocking layer comprises an epoxy-based material; and
wherein the blocking layer is fully removed from the edge region of the first semiconductor wafer during removal of the material from the second portion of the bonding layer.

10. The method of claim 8, wherein removing the material from the second portion of the bonding layer comprises:
etching the second portion of the bonding layer; and
planarizing the second portion of the bonding layer after etching the second portion of the bonding layer,
wherein the blocking layer is fully removed from the edge region of the first semiconductor wafer during the etching of the second portion of the bonding layer.

11. The method of claim 8, wherein a first lateral width of the first portion of the blocking layer is less than a second lateral width of the second portion of the blocking layer.

12. The method of claim 8, wherein forming the first portion of the blocking layer comprises:
depositing a photoresist layer over the first semiconductor wafer;
exposing a first portion of the photoresist layer, in the edge region, to radiation; and
removing a second portion of the photoresist layer after exposing the first portion of the photoresist layer to the radiation,
wherein the first portion of the photoresist layer corresponds to the first portion of the blocking layer.

13. The method of claim 12, wherein forming the second portion of the blocking layer comprises:
depositing another photoresist layer over the first semiconductor wafer;
exposing a first portion of the other photoresist layer, in the edge region, to radiation; and
removing a second portion of the other photoresist layer after exposing the first portion of the other photoresist layer to the radiation,
wherein the first portion of the other photoresist layer corresponds to the second portion of the blocking layer.

14. The method of claim 8, further comprising:
forming a third portion of the blocking layer on the second portion of the blocking layer,
wherein the third portion of the blocking layer fills in a third portion of the edge region, and
wherein removing the material from the second portion of the bonding layer comprises:
removing the material from the second portion of the bonding layer after forming the third portion of the blocking layer.

15. The method of claim 14, wherein a first lateral width of the second portion of the blocking layer is less than a second lateral width of the third portion of the blocking layer.

16. The method of claim 8, wherein forming the bonding layer comprises forming the first bonding layer using a precursor that contains an ester of orthosilicate acid.

17. The method of claim 8, wherein forming the bonding layer comprises forming the first bonding layer using a precursor that contains tetraethyl orthosilicate (TEOS).

18. A semiconductor device, comprising:
a first semiconductor die; and
a second semiconductor die bonded with the first semiconductor die at a bonding interface such that the first semiconductor die and the second semiconductor die are vertically arranged in the semiconductor device,
wherein the bonding interface comprises:
a first bonding layer of the first semiconductor die that is directly bonded with a second bonding layer of the second semiconductor die,
wherein at least one of the first bonding layer or the second bonding layer has a non-uniform thickness across the bonding interface, and
wherein the first bonding layer and the second bonding layer are fully bonded across the bonding interface between opposing edges of the semiconductor device.

19. The semiconductor device of claim 18, wherein a first thickness of the first bonding layer in an edge region of the semiconductor device is greater than a second thickness of the first bonding layer in a non-edge region of the semiconductor device.

20. The semiconductor device of claim 19, wherein a third thickness of the second bonding layer in the edge region of the semiconductor device is greater than a fourth thickness of the second bonding layer in the non-edge region of the semiconductor device.
